(19) United States
(12) Patent Application Publication
(10) Pub. No.: US 2024/0290624 A1
(43) Pub. Date: Aug. 29, 2024

(54) PROTECTIVE FILM, PROTECTIVE FILM AGENT, AND METHOD OF PROCESSING WORKPIECE

(71) Applicant: DISCO CORPORATION, Tokyo (JP)

(72) Inventors: Sho OSAWA, Tokyo (JP); Senichi RYO, Tokyo (JP); Yukinobu OHURA, Tokyo (JP); Shin TABATA, Tokyo (JP)

(21) Appl. No.: 18/439,028

(22) Filed: Feb. 12, 2024

(30) Foreign Application Priority Data
Feb. 22, 2023 (JP) 2023-026595

(51) Int. Cl. H01L 21/3065; C09D 5/32; C09D 123/08; H01L 21/027; H01L 21/02

(52) U.S. Cl. CPC H01L 21/3065; C09D 5/32; C09D 123/0853; H01L 21/0275; H01L 21/0206

(57) ABSTRACT

A protective film is disposed on a surface of a workpiece has a hardness in a range from 0.0093 GPa to 0.13 GPa. A protective film agent includes a water-soluble resin, a light absorbing agent, a plasticizer, and a solvent in which the water-soluble resin, the light absorbing agent, and the plasticizer are dissolved. The ratio of the mass of the plasticizer to a mass of the water-soluble resin is in a range from 15% to 53%, and a protective film formed from the protective film agent has a hardness in a range from 0.0093 GPa to 0.13 GPa.

### BACKGROUND OF THE INVENTION

### Field of the Invention

The present invention relates to a protective film to be disposed on a surface of a workpiece when plasma etching is performed on the workpiece, a protective film agent from which a protective film is to be formed, and a method of processing a workpiece by performing plasma etching on the workpiece using a protective film disposed on the workpiece as a mask.

### Description of the Related Art

Device chips incorporating devices such as integrated circuits (ICs) and large-scale-integration (LSI) circuits are widely used in electronic devices such as cellular phones and personal computers (PCs). Device chips are manufactured by processing semiconductor wafers (hereinafter also referred to as “workpieces”) such as monocrystalline silicon substrates. Device chips are manufactured from a workpiece as follows. A grid of projected processing lines is established on a face side of the workpiece. Then, devices such as ICs are constructed in respective rectangular areas demarcated on the face side of the workpiece by the projected processing lines.

Next, a grinding apparatus grinds a reverse side of the workpiece to thin down the workpiece to a predetermined thickness. Thereafter, the workpiece is divided along the projected processing lines into a plurality of pieces incorporating the respective devices by a dicing apparatus such as a cutting apparatus or a laser processing apparatus. In this manner, the workpiece is divided into individual device chips referred to as the pieces. In recent years, a process of dividing workpieces into device chips using a plasma etching apparatus, rather than the cutting apparatus or the laser processing apparatus, has been developed and put to practical use.

For dividing a workpiece according to plasma etching, first, the face side of the workpiece is covered with a water-soluble protective film, for example. Then, a laser beam is applied to the workpiece along the projected processing lines, removing strip-regions in the protective film along the projected processing lines by laser ablation. Thereafter, using the remaining protective film as a mask, plasma matching is performed on the workpiece, dividing the workpiece into device chips along the projected processing lines (see, for example, JP 2016-207737A). However, the customary process of dividing the workpiece according to plasma etching using the protective film as the mask is liable to reduce quality with which the workpiece is processed.

Research conducted by the applicant has revealed that in the vicinity of the projected processing lines on the face side of the workpiece, the protective film tends to be peeled off from the face side of the workpiece, allowing the plasma to enter clearances beneath the peeled protective film and etch the face side of the workpiece.

### SUMMARY OF THE INVENTION

The present invention has been made in view of the above problems. It is an object of the present invention to increase the quality with which a workpiece is divided by plasma etching by ensuring higher intimate contact between a protective film and the face side of the workpiece.

In accordance with an aspect of the present invention, there is provided a protective film to be disposed on a surface of a workpiece. The protective film has a hardness in a range from 0.0093 GPa to 0.13 GPa.

In accordance with another aspect of the present invention, there is provided a protective film agent including a water-soluble resin, a light absorbing agent, a plasticizer, and a solvent in which the water-soluble resin, the light absorbing agent, and the plasticizer are dissolved, in which the ratio of the mass of the plasticizer to a mass of the water-soluble resin is in a range from 15% to 53%, and a protective film formed from the protective film agent has a hardness in a range from 0.0093 GPa to 0.13 GPa.

Preferably, the water-soluble resin is at least one selected from a group consisting of polyvinyl alcohol, a vinyl acetate-vinyl pyrrolidone copolymer, and polyvinyl pyrrolidone, and the plasticizer is trimethylol propane. Preferably, the solvent includes water, and a ratio of a mass of water to a mass of the protective film agent is 50% or more.

In accordance with still another aspect of the present invention, there is provided a method of processing a workpiece, including a covering step of covering a surface of the workpiece with a protective film having a hardness in a range from 0.0093 GPa to 0.13 GPa, after the covering step, an irradiating step of irradiating the protective film along projected processing lines established on the workpiece with a pulsed laser beam having a wavelength absorbable by the protective film, thereby removing portions of the protective film along the projected processing lines to expose portions of the workpiece, and after the irradiating step, a plasma etching step of performing plasma etching on the exposed portions of the workpiece using the protective film as a mask.

The protective film according to the aspect of the present invention has a hardness in a range from 0.0093 GPa to 0.13 GPa. The hardness of the protective film in the above range is effective to reduce the shrinkage stress of the protective film and hence increase the intimate contact between the protective film and the surface of the workpiece, resulting in an increase in the quality with which the workpiece is processed by plasma etching.

Since the protective film agent according to the other aspect of the present invention contains the plasticizer, the hardness of the protective film is lower than if it is free of the plasticizer. As the shrinkage stress of the protective film is reduced, the intimate contact between the protective film and the surface of the workpiece is increased, thereby increasing the quality with which the workpiece is processed by plasma etching.

In the covering step of the method of processing a workpiece according to the still other aspect of the present invention, the surface of the workpiece is covered with the protective film whose hardness is in the range from 0.0093 GPa to 0.13 GPa. The range of the hardness of the protective film can reduce the shrinkage stress of the protective film, thereby increasing the intimate contact between the protective film and the surface of the workpiece. As a result, the quality with which the workpiece is processed by plasma etching can be increased.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a workpiece;

FIG. 2 is a flowchart of a method of processing a workpiece;

FIG. 3 is a fragmentary side elevational view, partly in cross section, illustrating the manner in which a face side of a workpiece is coated with a protective film agent;

FIG. 4 is a fragmentary side elevational view, partly in cross section, illustrating the manner in which the face side of the workpiece is covered with a protective film formed from the protective film agent;

FIG. 5 is a fragmentary side elevational view, partly in cross section, illustrating the manner in which a portion of the protective film is removed by a laser beam;

FIG. 6 is a fragmentary side elevational view, partly in cross section, illustrating a mask provided by the protective film processed by the laser beam;

FIG. 7 is a side elevational view, partly in cross section, illustrating a plasma etching apparatus;

FIG. 8 is a fragmentary side elevational view, partly in cross section, illustrating the manner in which the workpiece is processed in a plasma etching step by the plasma etching apparatus;

FIG. 9 is a fragmentary side elevational view, partly in cross section, illustrating the workpiece after the plasma etching step;

FIG. 10A is a photographic representation of a portion of a face side of a workpiece after a mask is formed thereon from a protective film agent according to Inventive Example 1 and the workpiece is processed by plasma etching;

FIG. 10B is a photographic representation of a portion of a face side of a workpiece after a mask is formed thereon from a protective film agent according to Comparative Example 1 and the workpiece is processed by plasma etching;

FIG. 11A is a photographic representation of a portion of a face side of a workpiece after a mask is formed thereon from a protective film agent according to Inventive Example 2 and the workpiece is processed by plasma etching;

FIG. 11B is a photographic representation of a portion of a face side of a workpiece after a mask is formed thereon from a protective film agent according to Comparative Example 2 and the workpiece is processed by plasma etching;

FIG. 12A is a photographic representation of a portion of a face side of a workpiece after a mask is formed thereon from a protective film agent according to Inventive Example 3 and the workpiece is processed by plasma etching;

FIG. 12B is a photographic representation of a portion of a face side of a workpiece after a mask is formed thereon from a protective film agent according to Comparative Example 3 and the workpiece is processed by plasma etching;

FIG. 13A is a photographic representation of a portion of a face side of a workpiece after a mask is formed thereon from a protective film agent according to Inventive Example 4 and the workpiece is processed by plasma etching;

FIG. 13B is a photographic representation of a portion of a face side of a workpiece after a mask is formed thereon from a protective film agent according to Comparative Example 4 and the workpiece is processed by plasma etching;

FIG. 14A is a photographic representation of a portion of a face side of a workpiece after a mask is formed thereon from a protective film agent according to Inventive Example 5 and the workpiece is processed by plasma etching;

FIG. 14B is a photographic representation of a portion of a face side of a workpiece after a mask is formed thereon from a protective film agent according to Comparative Example 5 and the workpiece is processed by plasma etching;

FIG. 15A is a photographic representation of a portion of a face side of a workpiece after a mask is formed thereon from a protective film agent according to Inventive Example 6 and the workpiece is processed by plasma etching;

FIG. 15B is a photographic representation of a portion of a face side of a workpiece after a mask is formed thereon from a protective film agent according to Comparative Example 6 and the workpiece is processed by plasma etching;

FIG. 16A is a photographic representation of a portion of a face side of a workpiece after a mask is formed thereon from a protective film agent according to Inventive Example 7 and the workpiece is processed by plasma etching;

FIG. 16B is a photographic representation of a portion of a face side of a workpiece after a mask is formed thereon from a protective film agent according to Comparative Example 7 and the workpiece is processed by plasma etching;

FIG. 17A is a photographic representation of a portion of a face side of a workpiece after a mask is formed thereon from a protective film agent according to Inventive Example 8 and the workpiece is processed by plasma etching;

FIG. 17B is a photographic representation of a portion of a face side of a workpiece after a mask is formed thereon from a protective film agent according to Inventive Example 9 and the workpiece is processed by plasma etching;

FIG. 17C is a photographic representation of a portion of a face side of a workpiece after a mask is formed thereon from a protective film agent according to Inventive Example 10 and the workpiece is processed by plasma etching;

FIG. 17D is a photographic representation of a portion of a face side of a workpiece after a mask is formed thereon from a protective film agent according to Inventive Example 11 and the workpiece is processed by plasma etching;

FIG. 18A is a fragmentary cross-sectional view schematically illustrating the manner in which the protective film shrinks;

FIG. 18B is a fragmentary cross-sectional view schematically illustrating the manner in which a plasma enters between the protective film and the face side of the workpiece;

FIG. 19A is a photographic representation of a portion of a mask formed from a protective film agent containing a plasticizer at a first ratio after a laser beam applying step;

FIG. 19B is a photographic representation of a portion of a mask formed from a protective film agent containing a plasticizer at a second ratio after the laser beam applying step;

FIG. 19C is a photographic representation of a portion of a mask formed from a protective film agent containing a plasticizer at a third ratio after the laser beam applying step;

FIG. 19D is a photographic representation of a portion of a mask formed from a protective film agent containing a plasticizer at a fourth ratio after the laser beam applying step; and

FIG. 19E is a photographic representation of a portion of a mask formed from a protective film agent containing a plasticizer at a fifth ratio after the laser beam applying step.

### DETAILED DESCRIPTION OF THE PREFERRED EMBODIMENT

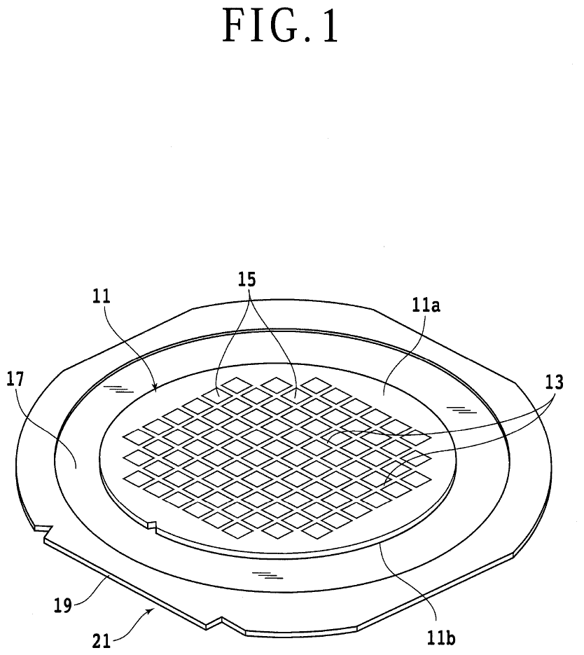

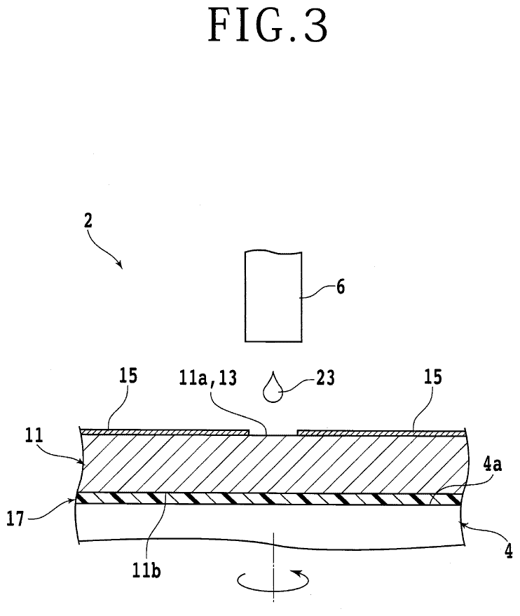

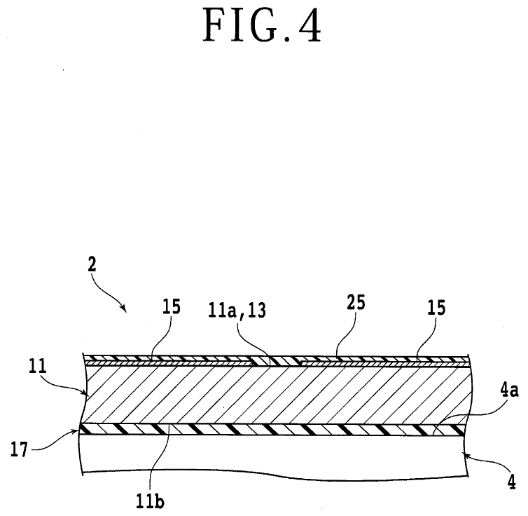

A preferred embodiment of the present invention will be described below with reference to the accompanying drawings. A protective film agent 23 (see FIG. 3) according to the present embodiment represents a plasma etching protective agent that is used as a material from which to form a protective film, i.e., a plasma etching protective film, 25 (see FIG. 4). The protective film 25 is used on a workpiece 11 (see FIG. 1) when the workpiece 11 is processed by plasma etching, for example, to mask devices 15 (see FIG. 1) such as ICs on the workpiece 11 to prevent the devices 15 from being damaged by a plasma.

FIG. 1 illustrates, in perspective, the workpiece 11 according to the present embodiment. As illustrated in FIG. 1, the workpiece 11 includes a monocrystalline silicon substrate shaped as a circular plate, i.e., a wafer, and has a circular face side (one surface) 11a and a circular reverse side (other surface) 11b opposite the face side 11a. A plurality of intersecting projected processing lines or streets 13 are established on the face side 11a of the workpiece 11. The projected processing lines 13 demarcate a plurality of rectangular areas in the face side 11a, and the devices 15 such as ICs are constructed in the respective areas.

A circular tape (dicing tape) 17 that is larger than the reverse side 11b in diameter is affixed to the reverse side 11b of the workpiece 11. The tape 17 has an outer circumferential edge portion to which there is affixed one surface of an annular frame 19 of metal that is larger than the workpiece 11 in diameter. Therefore, the workpiece 11 illustrated in FIG. 1 is supported by the annular frame 19 through the tape 17, i.e., integrated with the tape 17 and the annular frame 19. The workpiece unit 21 represents the integrated workpiece 11, tape 17 and annular frame 19. The workpiece 11 will be processed while being incorporated in the workpiece unit 21. According to the present invention, however, the tape 17 and the annular frame 19 are not indispensable. The workpiece 11 may be processed while not being integrated with the tape 17 and the annular frame 19.

According to the present embodiment, processing the workpiece 11 means plasma-etching the workpiece 11 and particularly cutting the workpiece 11 along the projected processing lines 13 by way of plasma etching, i.e., plasma dicing. For performing plasma dicing on the workpiece 11, the protective film 25 is formed from the protective film agent 23 on the face side 11a of the workpiece 11.

The protective film agent 23 contains a water-soluble resin. The water-soluble resin is a high-molecular compound that is capable of dissolving 0.5 g or more of itself in 100 g of water at 25° C., for example. The high-molecular compound may be polyvinyl pyrrolidone (hereinafter referred to as PVP), polyvinyl alcohol (hereinafter referred to as PVA), hydroxypropyl cellulose (hereinafter referred to as HPC), hydroxypropyl methylcellulose, polyethylene glycol, polyethylene oxide, methylcellulose, ethylcellulose, polyacrylic acid, poly-N-vinyl acetoamide, polyglycerin, polyoxazoline (e.g., poly (2-methyl-2-oxazoline), poly (2-ethyl-2-oxazoline), or poly (2-propyl-2-oxazoline)), poly-p-hydroxystyrene, polystyrene sulfonic acid, styrene maleic acid, or (meta) acrylic resin.

Furthermore, a copolymer of such a high-molecular compound may be used as the water-soluble resin. The copolymer may be a polyvinyl alcohol-acrylic acid-methyl methacrylate copolymer, a vinyl acetate-vinyl pyrrolidone copolymer (hereinafter referred to as VA), an ethylene-vinyl alcohol copolymer, a polyvinyl alcohol-polyethylene glycol copolymer, or the like. Either one of the high-molecular compounds and the copolymers referred to above may be used independently as the water-soluble resin, or some of the high-molecular compounds and the copolymers referred to above may be used in combination as the water-soluble resin. In other words, the protective film agent 23 may contain one of the above water-soluble resins independently or two or more of the water-soluble resins in combination.

The protective film agent 23 further contains a light absorbing agent capable of absorbing at least ultraviolet rays (preferably, wavelength light having wavelengths in the range from 250 nm to 400 nm). The light absorbing agent is represented by, for example, a water-soluble compound having a flavone structure, a flavonol structure, or an isoflavone structure. Such a compound has a capability of sufficiently absorbing ultraviolet rays (e.g., a laser beam having a wavelength of 355 nm). The water-soluble compound refers to a compound capable of dissolving 0.5 g or more of itself in 100 g of water at 25° C., for example. The flavone structure is expressed by the following chemical formula (1) where R indicates a hydrogen atom, a substituent, or a sugar chain.

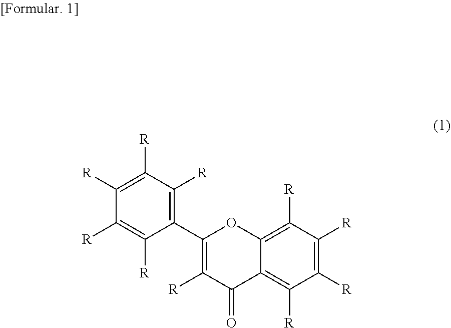

The flavonol structure is expressed by the following chemical formula (2) where R indicates a hydrogen atom, a substituent, or a sugar chain.

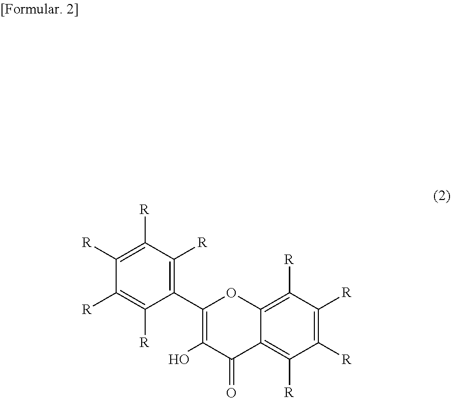

The isoflavone structure is expressed by the following chemical formula (3) where R indicates a hydrogen atom, a substituent, or a sugar chain.

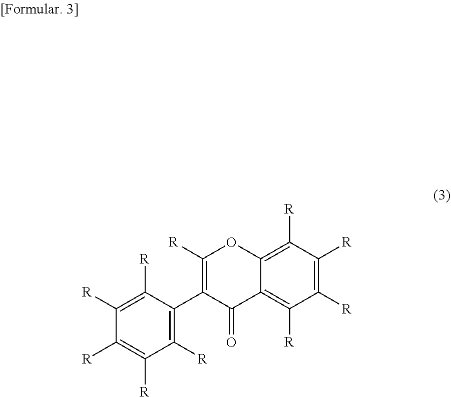

The compound may typically be isorhamnetin, flavonol, 4′-hydroxyflavone, 5-hydroxyflavone, acacetin, wogonoside, 3-hydroxy-4′-methoxyflavone, 7, 8-dihydroxyflavone, epimedin C, quercetin, baicalin, nobiletin, fisetin, rutin, icariin, icaritin, 7-hydroxyflavone, morin, kaempferide, hesperidin, 6-hydroxyflavone, kaempferol, wogonin, isoorientin, 5-methoxyflavone, luteolin, myricitrin, 3-methylflavone-8-carboxylic acid, 6-methylflavone, apigenin, 3-methoxyflavone, baicalein, 3,4′-dihydroxyflavone, orientin, 3′,4′-dihydroxyflavone, methylhesperidin, chrysin, 6-methoxyflavone, tangeretin, diosmetin, galangin, flavone, eupatilin, diosmin, neodiosmin, troxerutin, 2-(2-amino-3-methoxyphenyl) chromone, flavonol-2′-sulfonic acid, flavoxate, genistein, tectoridin, ononin, demethyltexasin, ipriflavone, neobavaisoflavone, sophoricoside, irisflorentin, puerarin, biochanin A, formononetin, tectorigenin, 7-methoxy-5-methylisoflavone, 4′,6,7-trimethoxyisoflavone, daidzein, genistin, dihydrodaidzein, or daidzin. However, the protective film agent 23 may contain other light absorbing agents.

In order for the light absorbing agent to be highly water-soluble, any of the compounds described above that can be used as the light absorbing agent should preferably be a transglycosylation compound. Using a transglycosylation compound as the light absorbing agent in the protective film agent 23, it is easy to increase the concentration of the light absorbing agent for higher absorbance. The transglycosylation compound is a compound with a sugar chain bonded thereto and is also called glycoside. The sugar chain may be either monosaccharide or oligosaccharide (oligomer) providing it is in a state for making the compound (substrate) water-soluble.

The sugar chain may typically be glucose, mannose, galactose, altrose, allose, talose, gulose, idose, xylose, arabinose, ribose, lyxose, apiose, erythrose, threose, fructose, psicose, sorbose, tagatose, ribulose, xylulose, erythrulose, sedoheptulose, coriose, glyceraldehyde, dihydroxyacetone, trehalose, isotrehalose, kojibiose, sophorose, nigerose, laminaribiose, maltose, cellobiose, isomaltose, gentiobiose, deoxyribose, fucose, rhamnose, glucosamine, galactosamine, glycerin, xylitol, sorbitol, glucuronic acid, galacturonic acid, ascorbic acid, glucuronolactone, gluconolactone, fructooligosaccharide, galactooligosaccharide, or lactosucrose. Alternatively, the sugar chain may be a derivative of any of these compounds.

Transglycosylation compounds that are particularly preferable as the light absorbing agent according to the present embodiment (i.e., the transglycosylation compound having the flavone structure, the flavonol structure, or the isoflavone structure) are, for example, transglycosylation rutin (e.g., α-gulcosyl rutin (hereinafter referred to as a-G rutin)) and transglycosylation hesperidin. Transglycosylation compounds contain compounds obtained by synthesis reactions as well as naturally occurring compounds. The synthesis reactions include chemical syntheses that use artificial reaction reagents and enzymatic syntheses that use natural glycosyltransferases (protein), and these syntheses are selected depending on the purpose.

Glycosyltransferases for realizing transglycosylation include fucosyltransferase, galactosyltransferase, sialyltransferase, gulcanotransferase, etc. that are used depending on the type of the saccharide. For example, a compound (also called enzyme-treated rutin or enzyme-treated isoquercitrin) where a sugar chain is additionally given by an enzymatic reaction to natural rutin where two rutinoses are given to quercetin that is a type of flavonol is also included as the transglycosylation rutin. This also holds true for transglycosylation hesperidin and other transglycosylation compounds (the transglycosylation compound having the flavone structure, the flavonol structure, or the isoflavone structure).

By thus adding a sugar chain having many hydroxyl groups to a compound (substrate) by a glycosyltransferase, the solubility of the compound into water can be increased. Using a compound that is highly water-soluble such as a transglycosylation compound as the light absorbing agent, the concentration of the light absorbing agent in the protective film agent 23 can be increased for higher absorbance. Similarly, the compounds described above for use as the light absorbing agent should preferably have a polar group (a hydroxyl group, ether, amine, a carboxyl group, or an amide group) as a substituent for achieving much higher water solubility. Using such a compound as the light absorbing agent, the concentration of the light absorbing agent in the protective film agent 23 can be increased for higher absorbance. Compounds having other substituents may also be used as the light absorbing agent.

Moreover, a cinnamic acid derivative such as ferulic acid, caffeine acid, or chlorogenic acid or a benzophenone derivative such as polyhydroxy benzophenone or 2-hydroxy-4-methoxybenzophenone-5-sulfonic acid may be used as the light absorbing agent. Either one of the compounds described above may be used independently as the light absorbing agent, or some of the compounds described above may be used in combination as the light absorbing agent. In other words, the protective film agent 23 may contain one of the above light absorbing agents independently or two or more of the above light absorbing agents in combination.

The protective film agent 23 further contains a plasticizer. According to the present embodiment, the plasticizer has a function to enter between molecular chains of the water-soluble resin to lower the bonding strength between the molecular chains. The protective film 25 that contains the plasticizer is more pliable than if it is free of the plasticizer. In other words, the plasticizer has a function to lower the hardness of the protective film 25.

According to a model in which deformations of a film are highly simplified, a shrinkage stress acting on the film is proportional to the product of the elastic modulus of the film and the amount of shrinkage strain of the film, and the elastic modulus of the film is substantially commensurate with the hardness of the film. Therefore, a reduction in the hardness of the protective film 25 causes a reduction in the shrinkage stress of the protective film 25. The applicant has assumed that the intimate contact between the protective film 25 and the face side 11a of the workpiece 11 can be increased by a reduction in the shrinkage stress of the protective film 25, leading to an increase in the quality with which the workpiece 11 is processed by plasma etching.

The plasticizer may be glycerin, diglycerin, sorbitol, ethylene glycol, diethylene glycol, triethylene glycol, tetraethylene glycol, polyethylene glycol, propylene glycol, dipropylene glycol, neopentyl glycol, trimethylol propane (hereinafter referred to as TMP), polyether polyol, 2-methyl-1,3-propane diol, or ethanol amine.

In other words, the protective film agent 23 may contain one of the above plasticizers independently or two or more of the above plasticizers in combination. The protective film agent 23 that contains the plasticizer is able to make the protective film 25 hard in a predetermined range (e.g., from 0.0093 GPa to 0.13 GPa). Particularly preferable among the above plasticizers is one or two or more in combination of TMP, glycerin, sorbitol, triethylene glycol, polyethylene glycol, propylene glycol, dipropylene glycol, and 2-methyl-1,3-propane diol.

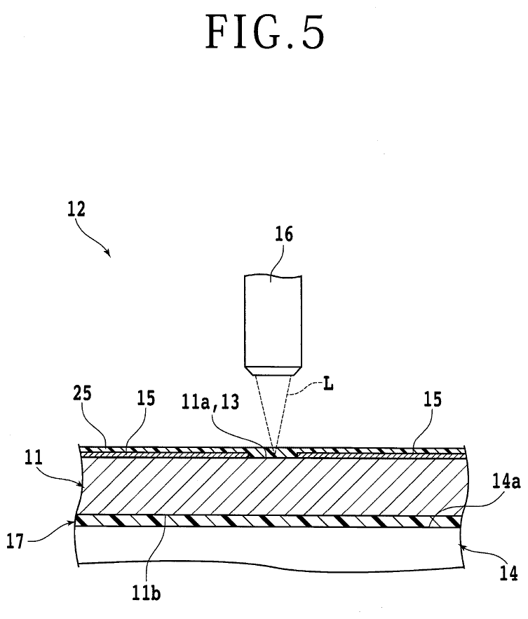

As described in detail later, in order to increase the intimate contact between the protective film 25 and the face side 11a of the workpiece 11, it is preferable to make the ratio of the mass of the plasticizer to the mass of one or more water-soluble resins equal to 15% or more. In order to prevent the protective film 25 from being peeled off at the time the protective film 25 is ablated by a pulsed laser beam L (see FIG. 5), it is preferable to make the ratio of the mass of the plasticizer to the mass of one or more water-soluble resins equal to 53% or less.

The protective film agent 23 further contains a solvent. The water-soluble resin, the light absorbing agent, and the plasticizer referred to above are dissolved in the solvent. The solvent is water (i.e., pure water), for example. However, the protective film agent 23 may contain another solvent (typically an organic solution that mixes with water) as well as water.

The organic solution may be, for example, propylene glycol monomethyl ether (hereinafter referred to as PGME), methanol, ethanol, isopropanol, acetone, or tetrahydrofuran. However, the solvent in the protective film agent 23 contains water as its chief component. A ratio of the mass of water to a mass of a protective film agent 23 is 50% or more, preferably 60% or more. According to an example, the ratio of the mass of the organic solution to the mass of the protective film agent 23 is in the range from 10% to 20%, e.g., 15%.

The protective film agent 23 may contain one of the organic solutions independently or two or more of the organic solutions in combination. According to the present embodiment, since a compound that is highly water-soluble is used as the light absorbing agent, the concentration of the light absorbing agent in the protective film agent 23 can be increased for higher absorbance without using a large amount of the organic solution as the solvent.

Specifically, even if the ratio of the solvent to the protective film agent 23 is 50 wt % or more, preferably 60 wt % or more, or more preferably 70 wt % or more, the protective film 25 can realize sufficiently high absorbance. In this regard, the protective film agent 23 is different from liquid photosensitive resins that contain an organic solution as a main constituent, for forming photoresist films in a photolithographic process.

An oxidation inhibitor may be added to the protective film agent 23 for the purpose of restraining its deterioration over time. The oxidation inhibitor may typically be L-ascorbic acid (i.e., vitamin C), D-araboascorbic acid, ethylascorbic acid, or ascorbic acid 2-glucoside. Any of these compounds may be added independently to the protective film agent 23 or some of compounds may be added in combination to the protective film agent 23. Moreover, an antiseptic may be added to the protective film agent 23 for the purpose of restraining its corrosion. The antiseptic may typically be 4-hydroxymethylbenzoate, but not limited thereto.

The proportions of the water-soluble resin, the light absorbing agent, the plasticizer, and the solvent contained in the protective film agent 23 are set in respective ranges for appropriately realizing the performance of the protective film 25 as a target to be achieved. Generally, the higher the proportion of the water-soluble resin contained in the protective film agent 23 is, the higher the viscosity of the protective film agent 23. Under identical coating conditions, therefore, the protective film 25 formed from the protective film agent 23 where the proportion of the water-soluble resin contained therein is higher tends to be thicker.

As long as water-soluble resins have the same molecular structure, generally, the smaller the molecular weight of a water-soluble resin is, the more soluble the water-soluble resin becomes in the solvent. Therefore, among protective film agents 23 containing respective water-soluble resins that have the same weight percent concentration, a protective film agent 23 containing a water-soluble resin that has a smaller molecular weight has a lower viscosity and can be transported more easily.

From the standpoints of the thickness of the protective film 25 and the ease with which to transport the protective film agent 23, the weight-average molecular weight of the water-soluble resin should preferably be 250, 000 or smaller and more preferably be 100,000 or smaller. The light absorbing agent may be contained in a desired amount up to its solubility insofar as it does not impair the performance of the protective film agent 23.

It is preferable for the protective film agent 23 to contain an amount of light absorbing agent whose absorbance is 5.0 or more per thickness of 1 cm (i.e., length along the optical path) at a wavelength of 355 nm providing the protective film agent 23 is diluted 200 times by pure water. However, the absorbance of 5.0 or more is not essential.

According to an experiment conducted by the applicant, 50 parts by mass of a transglycosylation rutin (α-gulcosyl rutin (hereinafter referred to as αGR)) manufactured by Toyo Sugar Refining Co., Ltd. could be dissolved in pure water. In other words, αGR whose mass is one-half of the mass of a predetermined amount of pure water could be dissolved in the pure water.

The protective film agent 23 described above should preferably be passed through an ion exchange resin, thereby removing impurities such as metal ions from the protective film agent 23. The ion exchange performed on the protective film agent 23 by the ion exchange resin reduces the pH of the protective film agent 23 to 4 or less. Although it is preferable to reduce the pH of the protective film agent 23 to 4 or less from the standpoint of corrosion prevention, a base such as triethanolamine may be added to the protective film agent 23 to adjust the pH thereof to 4 or more.

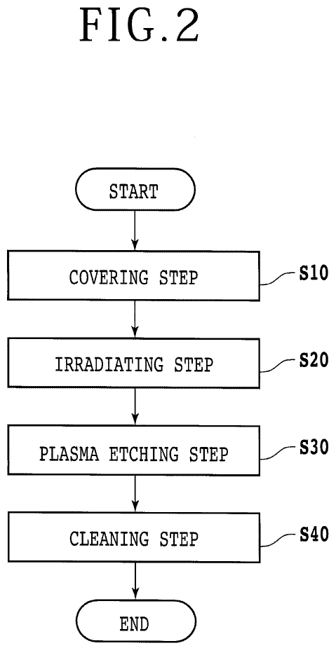

A method of processing the workpiece 11 will be described below with reference to FIGS. 2 through 9. FIG. 2 is a flowchart of the method of processing the workpiece 11. As illustrated in FIG. 2, the method includes covering step S10, irradiating step S20, plasma etching step S30, and cleaning step S40 that are successively carried out. First, as illustrated in FIG. 3, the face side 11a of the workpiece 11 is coated with the protective film agent 23, covering the face side 11a with the protective film 25, as illustrated in FIG. 4 (covering step S10). FIG. 3 illustrates in fragmentary side elevation, partly in cross section, the manner in which the face side 11a of the workpiece 11 is coated with the protective film agent 23. FIG. 4 illustrates in fragmentary side elevation, partly in cross section, the manner in which the face side 11a of the workpiece 11 has been covered with the protective film 25.

A spin coater 2 illustrated in FIG. 3 is used to coat the workpiece 11 with the protective film agent 23. The spin coater 2 includes a spinner table 4 for holding the workpiece 11 thereon. The spinner table 4 is coupled to a rotary actuator, not depicted, such as an electric motor. The spinner table 4 can be rotated by the rotary actuator about a rotational axis generally parallel to a vertical axis. The spinner table 4 has an upper surface including a portion functioning as a holding surface 4a for holding the workpiece 11 thereon.

To the holding surface 4a, there can be transmitted a negative pressure from a suction source, not depicted, such as a vacuum pump through a fluid channel, not depicted, defined in the spinner table 4. The spinner table 4 is surrounded by a plurality of clamps, not depicted, for securing the annular frame 19 supporting the workpiece 11 in place. The spin coater 2 also includes a nozzle 6 disposed above the spinner table 4 in alignment with the rotational axis of the spinner table 4 for dropping the protective film agent 23 from which to form the protective film 25.

In covering step S10, the workpiece 11 is held under suction on the holding surface 4a with the tape 17 interposed therebetween, and the annular frame 19 is secured in place by the clamps. The workpiece 11 is now held on the spinner table 4 with the face side 11a exposed upwardly. Then, the nozzle 6 drops the protective film agent 23 onto the face side 11a of the workpiece 11, and the spinner table 4 is rotated about its rotational axis, spreading the protective film agent 23 substantially uniformly over the face side 11a under centrifugal forces.

Coating conditions under which the workpiece 11 is coated with the protective film agent 23 may be varied depending on the diameter of the workpiece 11 and other variables. If the diameter of the workpiece 11 is 200 mm, then the coating conditions are typically as follows.
Amount of protective film agent: from 20 mL to 50 mL
Speed of rotation of spinner table: from 200 rpm to 3000 rpm
Period of rotation of spinner table: from 30 seconds to 360 seconds

The protective film agent 23 spread substantially uniformly over the face side 11a by rotating the spinner table 4 at the above speed of rotation for the above period of rotation turns into the protective film 25 that covers the face side 11a substantially in its entirety, as shown in FIG. 4. The protective film 25 formed in covering step S10 should preferably have a hardness in the range from 0.0093 GPa to 0.13 GPa. The protective film 25 formed in covering step S10 has a thickness of approximately 4.0 μm, for example. If the workpiece 11 is relatively thick or has a relatively high degree of etching resistance, then the protective film 25 should preferably have a thickness in excess of 4.0 μm.

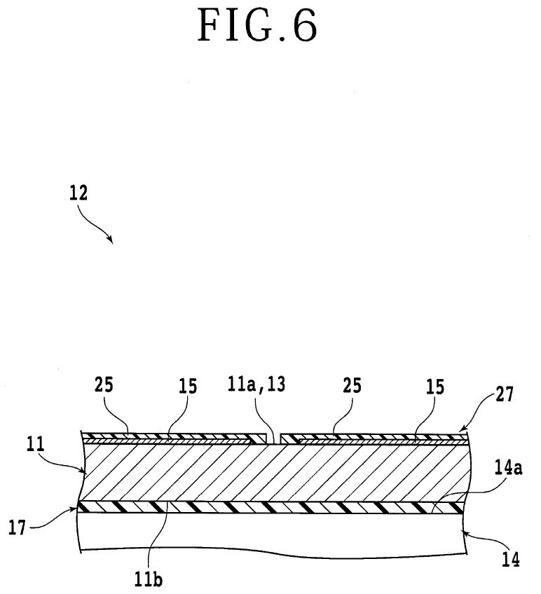

In case the thickness of the protective film 25 is in the range from 2.0 μm to 4.0 μm, it is easy to remove the protective film 25 with a laser beam applied thereto. Therefore, if plasma etching is performed on the workpiece 11 that is relatively thin, the protective film 25 should preferably have a thickness in the range from 2.0 μm to 4.0 μm. If the thickness of the protective film 25 is less than 2.00 μm, i.e., is too thin, since the protective film 25 is removed to a certain extent in subsequent plasma etching step S30, the protective film 25 is liable to fail to function as a mask 27 (see FIG. 6) for plasma etching.

Drying processes available in the art include natural drying, baking, irradiation to pulsed xenon light, and irradiation to infrared rays. The protective film agent 23 can quickly be dried by baking, irradiation to pulsed xenon light, or irradiation to infrared rays.

According to the present embodiment, the workpiece 11 is coated with the protective film agent 23 in a spin coating process performed by the spin coater 2. The spin coating process allows the protective film 25 to be formed relatively easily on the face side 11a of the workpiece 11 substantially in its entirety in the spin coating process. Alternatively, another coating process such as a spray coating process may be used to coat the workpiece 11 with the protective film agent 23. The spray coating process is available in variations such as two-fluid spray coating, ultrasonically atomized spray coating, and electrostatic spray coating. The spray coating process is advantageous in that it allows the protective film 25 to be formed well on the face side 11a that has relatively large surface irregularities.

After covering step S10, the face side 11a of the workpiece 11 is irradiated along the projected processing lines 13 with the pulsed laser beam L (see FIG. 5) that has a wavelength of 355 nm, for example, absorbable by the protective film 25. The pulsed laser beam L thus applied to the workpiece 11 removes portions of the protective film 25 that overlie the projected processing lines 13. The protective film 25 is partially removed, exposing portions of the workpiece 11 (irradiating step S20).

FIG. 5 illustrates in fragmentary side elevation, partly in cross section, the manner in which a portion of the protective film 25 is removed by the pulsed laser beam L. FIG. 6 illustrates in fragmentary side elevation, partly in cross section, the mask 27 provided by the protective film 25 processed by the pulsed laser beam L. Irradiating step S20 is carried out by a laser processing apparatus 12 illustrated in FIGS. 5 and 6. As illustrated in FIGS. 5 and 6, the laser processing apparatus 12 includes a chuck table 14 for holding the workpiece 11 thereon. The chuck table 14 is coupled to a rotary actuator, not depicted, such as an electric motor. The chuck table 14 can be rotated by the rotary actuator about a rotational axis generally parallel to a vertical axis.

The chuck table 14 is movable along a processing feed direction, i.e., a first horizontal direction, and an indexing feed direction, i.e., a second horizontal direction, by a table moving mechanism, not depicted, disposed beneath the chuck table 14. The processing feed direction and the indexing feed direction extend perpendicularly to each other and to the vertical direction.

The chuck table 14 has an upper surface including a portion functioning as a holding surface 14a for holding the workpiece 11 thereon. To the holding surface 14a, there can be transmitted a negative pressure from a suction source, not depicted, such as a vacuum pump through a fluid channel, not depicted, defined in the chuck table 14. The chuck table 14 is surrounded by a plurality of clamps, not depicted, for securing the annular frame 19 supporting the workpiece 11 in place. The laser processing apparatus 12 also includes a processing head 16 of a laser beam applying unit disposed above the chuck table 14 for applying the pulsed laser beam L.

The laser beam applying unit has a laser oscillator, not depicted, for emitting the pulsed laser beam L. The laser oscillator has a laser medium such as of Nd:YAG or Nd:YVO₄. The pulsed laser beam L emitted from the laser oscillator is converted into a pulsed laser beam having a predetermined harmonic, e.g., an ultraviolet wavelength, and then applied from the processing head 16 to the workpiece 11 while being focused in the vicinity of the face side 11a of the workpiece 11.

In irradiating step S20, the workpiece 11 is held under suction on the holding surface 14a with the tape 17 interposed therebetween, and the annular frame 19 is secured in place by the clamps. The workpiece 11 is now held on the chuck table 14 with the face side 11a exposed upwardly.

Then, the chuck table 14 is turned about its rotational axis by the rotary actuator until one, a target to be irradiated with the pulsed laser beam L, of the projected processing lines 13 on the workpiece 11 is aligned with the processing feed direction of the laser processing apparatus 12. The chuck table 14 is also positionally adjusted to position the processing head 16 above an extension of the target projected processing line 13.

Thereafter, as illustrated in FIG. 5, while the processing head 16 is applying the pulsed laser beam L to the face side 11a of the workpiece 11, the chuck table 14 is moved in the processing feed direction. At this time, the processing head 16 focuses the pulsed laser beam L on an exposed upper surface of the protective film 25 or within the protective film 25. Accordingly, the workpiece 11 is processed by the pulsed laser beam L thus applied thereto. Processing conditions under which the workpiece 11 is processed by the pulsed laser beam L are as follows.
Wavelength: 355 nm
Average output power: from 0.1 W to 100 W, e.g., 0.7 W
Beam spot diameter: from 1 μm to 100 μm, e.g., 15 μm
Repetitive frequency: from 100 kHz to 50000 kHz, e.g., 200 KHz
Pulse duration: from 10 fs to 500 ns, e.g., 9 ps
Processing feed speed: from 20 mm/s to 5000 mm/s, e.g., 600 mm/s

According to the present embodiment, the workpiece 11 is irradiated with the laser beam L under such conditions that the workpiece 11 is almost not processed by the laser beam L. However, the face side 11a of the workpiece 11 may be partially processed along the projected processing lines 13 by the laser beam L. A process of irradiating the workpiece 11 with the laser beam L along the target projected processing line 13 to remove a portion of the projective film 25 that overlies the target projected processing line 13 is performed along each of the projected processing lines 13, removing portions of the protective film 25 that overly the respective protective processing lines 13 and partially exposing the workpiece 11. In this manner, the protective film 25 is turned into the mask 27 that covers the areas corresponding to the respective devices 15.

The protective film 25 that has been formed by coating the face side 11a of the workpiece 11 with the protective film agent 23 and drying the applied protective film agent 23 contains the light absorbing agent having high absorbance at the ultraviolet wavelength, as described above. Therefore, the laser beam L is well absorbed by the protective film 25, appropriately removing the portions of the protective film 25 that have been irradiated with the laser beam L.

The protective film agent 23 according to the present embodiment contains the plasticizer, as described above. The plasticizer represents alcohol having a smaller molecular weight than the water-soluble resin. The plasticizer is dissolvable and sublimable more easily than the water-soluble resin in laser ablation. Therefore, the protective film agent 23 that contains the plasticizer makes the protective film 25 formed therefrom easier to remove in the laser ablation than if the protective film agent 23 contains no plasticizer. In other words, the protective film agent 23 that contains the plasticizer makes the protective film 25 removable more reliably.

After irradiating step S20, a plasma is caused to act on the workpiece 11 using the protective film 25 ablated by the laser beam L as the mask 27, thereby performing plasma etching on the portions of the workpiece 11 that are exposed through the mask 27 (plasma etching step S30).

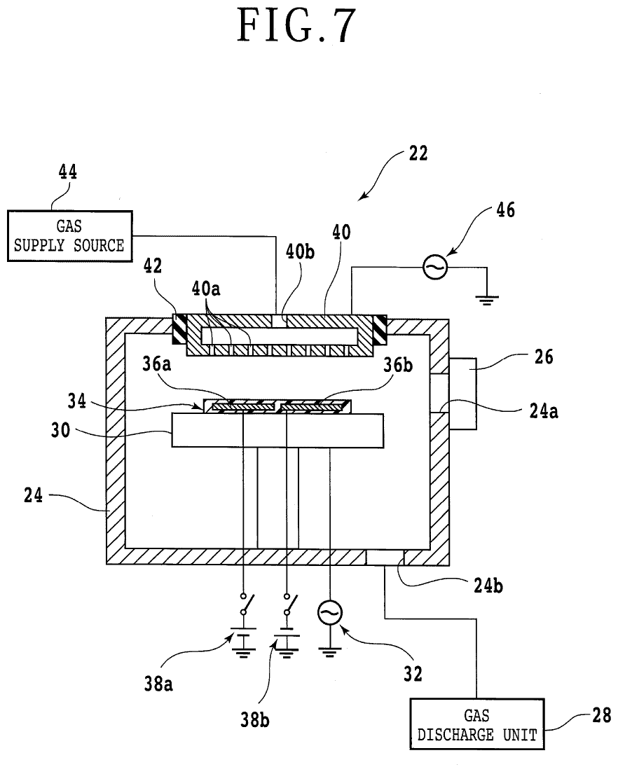

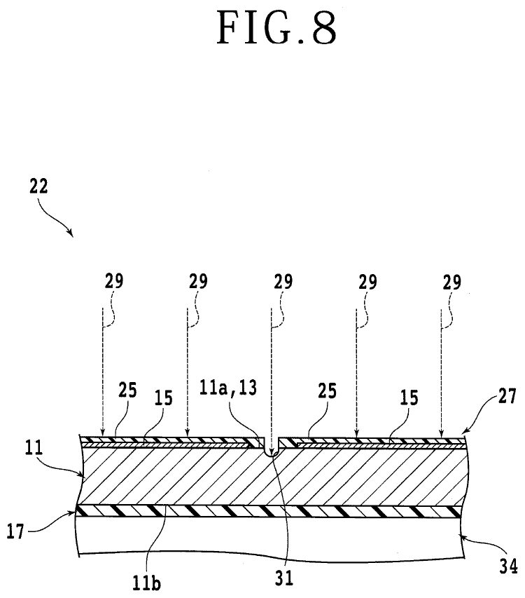

FIG. 7 illustrates in fragmentary side elevation, partly in cross section, a plasma etching apparatus 22 used in plasma etching step S30. In FIG. 7, some components of the plasma etching apparatus 22 are illustrated as symbols and blocks. FIG. 8 illustrates in fragmentary side elevation, partly in cross section, the manner in which the workpiece 11 is processed by plasma etching. According to the present embodiment, the plasma etching apparatus 22 is a capacitively coupled plasma (CCP) apparatus that generates a plasma between two metal plates. However, the plasma etching apparatus 22 is not limited to the CCP apparatus but may be any of other plasma etching apparatuses.

As illustrated in FIG. 7, the plasma etching apparatus 22 includes a vacuum chamber 24 having a processing space defined therein. The vacuum chamber 24 has a vertical side wall with an opening 24a defined therein that is large enough to allow the workpiece 11 and the annular frame 19 to pass therethrough. A cover 26 is movably disposed on an outer surface of the side wall for selectively covering the opening 24a. The cover 26 is coupled to an opening and closing mechanism, not depicted, for moving the cover 26 to selectively opening and closing the opening 24a.

When the cover 26 is moved to open the opening 24a, the workpiece 11 can be introduced through the opening 24a into the processing space in the vacuum chamber 24 or can be removed from the processing space in the vacuum chamber 24 through the opening 24a. The vacuum chamber 24 has a bottom wall with a gas discharge port 24b defined therein. The gas discharge port 24b is fluidly connected to a gas discharge unit 28 including a vacuum pump. When the gas discharge unit 28 is actuated, it discharges a gas from the processing space through the gas discharge port 24b, thereby evacuating the processing space.

The vacuum chamber 24 houses a lower electrode 30 disposed in the processing space. The lower electrode 30 is shaped as a circular plate made of an electrically conductive material and is electrically connected to a high-frequency power supply 32 disposed outside of the vacuum chamber 24. The high-frequency power supply 32 operates to mainly control the energy of a generated plasma 29 (see FIG. 8) as it is applied to the workpiece 11. An electrostatic chuck 34 is disposed on an upper surface of the lower electrode 30.

The electrostatic chuck 34 includes a pair of electrodes 36a and 36b that are electrically insulated from each other by a dielectric member made of alumina or aluminum nitride. The electrode 36a is electrically connected to the positive pole of a DC power supply 38a disposed outside of the vacuum chamber 24, whereas the electrode 36b is electrically connected to the negative pole of a DC power supply 38b disposed outside of the vacuum chamber 24. In the processing chamber, the workpiece 11 is placed on the electrostatic chuck 34 as illustrated in FIG. 8 and attracted to the electrostatic chuck 34 by electric forces acting between the electrodes 36a and 36b and the workpiece 11. Although the DC power supplies 38a and 38b are illustrated as two separate power supplies in FIG. 7, they may be replaced with a single DC power supply.

The vacuum chamber 24 has a ceiling wall to which there is attached an upper electrode 40 shaped as a circular plate made of an electrically conductive material with an insulating member 42 interposed therebetween. The upper electrode 40 has a lower surface with a plurality of gas ejection holes 40a defined therein. The gas ejection holes 40a are fluidly connected to a gas supply source 44 disposed outside of the vacuum chamber 24 through a gas supply port 40b defined in an upper surface of the upper electrode 40. The gas supply source 44 supplies a gas for plasma etching to the processing chamber in the vacuum chamber 24 through the gas ejection holes 40a for performing plasma etching on the workpiece 11 on the electrostatic chuck 34 with the plasma 29. The upper electrode 40 is electrically connected to a high-frequency power supply 46 disposed outside of the vacuum chamber 24. The high-frequency power supply 46 operates to generate the plasma 29.

For processing the workpiece 11 with the plasma, the opening and closing mechanism is actuated to move the cover 26 to open the opening 24a. Then, the workpiece unit 21 is introduced through the opening 24a into the processing chamber in the vacuum chamber 24 and placed on the electrostatic chuck 34. Specifically, the workpiece unit 21 is placed on the electrostatic chuck 34 such that the tape 17 is held in contact with an upper surface of the electrostatic chuck 34. Then, the electrostatic chuck 34 is energized to attract the workpiece 11 thereto while the mask 27 thereof is being exposed upwardly. Thereafter, the opening and closing mechanism is actuated to move the cover 26 to close the opening 24a, hermetically sealing the processing chamber in the vacuum chamber 24.

Then, the gas discharge unit 28 is actuated to evacuate the processing space to a predetermined pressure in the range from 1 Pa to 10 Pa, for example. While the gas supply source 44 is supplying the gas for plasma etching at a predetermined flow rate to the processing space, the high-frequency power supply 32 provides high-frequency electric power to the lower electrode 30 and the high-frequency power supply 46 provides high-frequency electric power to the upper electrode 40. As illustrated in FIG. 8, the plasma 29 that includes radicals and ions is generated between the lower electrode 30 and the upper electrode 40. The plasma 29 now etches the portions of the face side 11a of the workpiece 11 that are not covered with the mask 27.

The gas supplied from the gas supply source 44 is selected depending on the material of the workpiece 11, etc. For example, the generally-called Bosch process is performed for processing the workpiece 11 thicknesswise with relatively high selectivity, such as for dividing the workpiece 11 along the projected processing lines 13. In the plasma etching according to the present embodiment, three steps including a groove forming step, a film forming step, and a partial film removing step are successively repeated. In case the workpiece 11 includes a monocrystalline silicon substrate, it is processed as follows.

In the groove forming step, while a constant pressure is being maintained in the processing space in the vacuum chamber 24, the gas supply source 44 supplies SF₆ at a predetermined flow rate to the processing space, and the high-frequency power supplies 32 and 46 provide predetermined high-frequency electric power to the lower electrode 30 and the upper electrode 40. The plasma 29 that includes radicals and ions produced from SF₆ is now generated between the lower electrode 30 and the upper electrode 40, processing, i.e., etching, the portions of the face side 11a of the workpiece 11 that are not covered with the mask 27. As a consequence, shallow grooves 31 (one depicted in FIG. 8) are formed in the workpiece 11 along the projected processing lines 13.

In the film forming step after the groove forming step, while a constant pressure is being maintained in the processing space in the vacuum chamber 24, the gas supply source 44 supplies C₄F₈ at a predetermined flow rate to the processing space, and the high-frequency power supplies 32 and 46 provide predetermined high-frequency electric power to the lower electrode 30 and the upper electrode 40. A CF-based protective film, not depicted, is now deposited in each of the grooves 31 as a thin film that covers the inner surface of the groove 31. The CF-based protective film has a predetermined degree of resistance against the plasma 29 formed from SF₆.

In the partial film removing step after the film forming step, while a constant pressure is being maintained in the processing space in the vacuum chamber 24, the gas supply source 44 supplies SF₆ at a predetermined flow rate to the processing space, and the high-frequency power supplies 32 and 46 provide predetermined high-frequency electric power to the lower electrode 30 and the upper electrode 40. In the partial film removing step, the high-frequency electric power provided to the lower electrode 30 is set to a value larger than the high-frequency electric power provided to the lower electrode 30 in the groove forming step.

The larger high-frequency electric power provided to the lower electrode 30 makes the CF-based protective film deposited in each of the shallow grooves 31 more anisotropic with respect to the plasma etching by the plasma 29. Specifically, a portion of the CF-based protective film that is deposited on a bottom surface of the shallow groove 31 is preferentially processed. In other words, the portion of the CF-based protective film that covers the bottom surface of the shallow groove 31 is etched away, i.e., removed, better than portions of the CF-based protective film that covers side surfaces of the shallow groove 31 by the plasma 29 formed from SF₆.

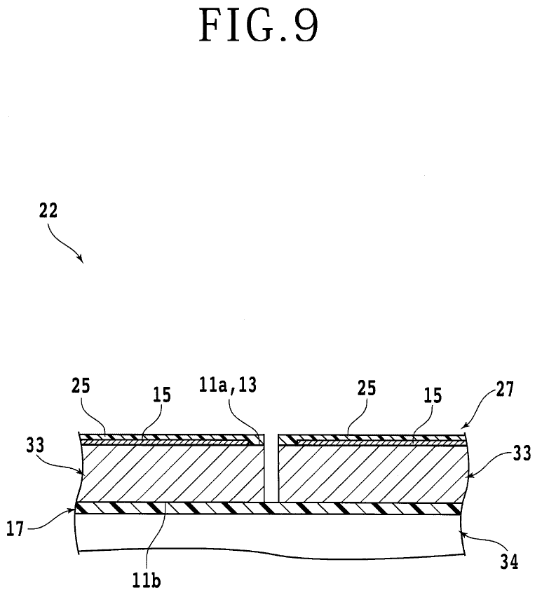

The three steps, i.e., the groove forming step, the film forming step, and the partial film removing step, are successively repeated to progressively deepen the grooves 31 until finally the workpiece 11 is divided along the projected processing lines 13, as illustrated in FIG. 9. In this fashion, the workpiece 11 is divided into a plurality of device chips 33.

FIG. 9 illustrates in fragmentary side elevation, partly in cross section, the workpiece 11 after plasma etching step S30. Since the protective film agent 23 according to the present embodiment contains the plasticizer, the hardness of the protective film 25 is reduced compared with the protective film agent 23 that contains no plasticizer. For example, the hardness of the protective film 25 is reduced to a range from 0.0093 GPa to 0.13 GPa.

As a reduction in the hardness of the protective film 25 causes a reduction in the shrinkage stress of the protective film 25, the intimate contact between the protective film 25 and the face side 11a of the workpiece 11 is increased, resulting in an increase in the quality with which the workpiece 11 is processed by plasma etching. Specifically, the plasma 29 is prevented from entering between the protective film 25 and the face side 11a of the workpiece 11 and hence etching the face side 11a of the workpiece 11 that is covered with the mask 27. Accordingly, the quality with which the workpiece 11 is processed by the plasma etching is increased.

Providing the thickness of the protective film 25 is in the range from 2.00 μm to 4.1 μm, the protective film 25 can reliably be removed by the laser ablation and can function as the mask 27 upon the plasma etching. In addition, the protective film agent 23 that contains the plasticizer and the light absorbing agent allows the protective film 25 to be reliably removed by the laser ablation.

After plasma etching step S30, the mask 27, i.e., the remaining protective film 25, is removed by way of cleaning (cleaning step S40). In cleaning step S40, a spinner cleaning apparatus, not depicted, is used to eject a two-fluid mixture of water and air to the protective film 25 on the face side 11a of the workpiece 11, removing the protective film 25 therefrom.

In cleaning step S40, inasmuch as the two-fluid mixture applied to the protective film 25 contains water, it can simply and reliably remove the light absorbing agent that is relatively highly water-soluble as well as the water-soluble resin. In other words, residuals caused by the light absorbing agent can be reduced compared with the case where a light absorbing agent that is of high affinity with organic solvents is used. In cleaning step S40, other cleaning processes than the two-fluid cleaning process, such as a high-pressure cleaning process, a vapor two-fluid cleaning process, and a micro/nano-bubble water cleaning process may be used to remove the protective film 25. In these cleaning processes, either water at normal temperature (cleaning water) or heated water may be used.

If it is difficult to remove the protective film 25 with only water, i.e., by way of one-fluid cleaning, then the protective film 25 may be removed from the workpiece 11 by a plasma process, a process of applying ultraviolet rays having a wavelength of 185 nm and/or a wavelength of 254 nm, for example, a process of applying excimer light having a wavelength of 172 nm, for example, or a cleaning process using ozone water.

Experiments conducted to confirm the advantages of the protective film agent 23 and their results will be described below. First, as indicated by Table 1 to be given later, a plurality of protective film agents 23 (Inventive Examples 1 through 11) having different kinds of water-soluble resins and different contents of light absorbing agents were prepared. In addition, as indicated by Table 2 to be given later, a plurality of protective film agents (Comparative Examples 1 through 7) free of the plasticizer (except Comparative Example 5) according to the present embodiment were also prepared. In each of Inventive Examples 1 through 11 and Comparative Examples 1 through 7, the light absorbing agent was αGR manufactured by Toyo Sugar Refining Co., Ltd. In Inventive Examples 6 and 7 and Comparative Examples 6 and 7, PGME was added for the purposes of reducing thickness irregularities of the protective film agent and increasing the smoothness thereof.

For illustrative purposes, the protective film agent, the protective film, and the mask in each of Inventive Examples 1 through 11 will be denoted by the respective reference numerals 23, 25, and 27, whereas the protective film agent, the protective film, and the mask in each of Comparative Examples 1 through 7 will not be denoted by respective reference numerals. The protective films in Inventive Examples 1 through 11 and Comparative Examples 1 through 7 will not be denoted by reference numerals when referred to together. This also holds true for the protective films and the masks.

### Inventive Example 1

15 parts by mass of PVP were gradually added to 75 parts by mass of pure water, and the solution was stirred to dissolve the PVP. Thereafter, 5 parts by mass of TMP were added to the solution, and the solution was stirred to dissolve the TMP. Then, 5 parts by mass of αGR were gradually added to the solution, and the solution was stirred to dissolve the αGR. In this manner, a protective film agent 23 according to Inventive Example 1 was obtained. PVP-K50 having a K value in the range from 48 to 52 was used as the PVP.

### Inventive Example 2

15 parts by mass of PVA were gradually added to 75 parts by mass of pure water, and the solution was stirred to dissolve the PVA. Thereafter, 5 parts by mass of TMP were added to the solution, and the solution was stirred to dissolve the TMP. Then, 5 parts by mass of αGR were gradually added to the solution, and the solution was stirred to dissolve the αGR. In this manner, a protective film agent 23 according to Inventive Example 2 was obtained. The degree of polymerization of the PVA used was 300, and the degree of saponification thereof was in the range from 78.5 mol % to 81.5 mol %.

### Inventive Example 3

15.00 parts by mass of HPC were gradually added to 77.75 parts by mass of pure water, and the solution was stirred to dissolve the HPC. Thereafter, 2.25 parts by mass of TMP were added to the solution, and the solution was stirred to dissolve the TMP. Then, 5.00 parts by mass of αGR were gradually added to the solution, and the solution was stirred to dissolve the αGR. In this manner, a protective film agent 23 according to Inventive Example 3 was obtained. HPC-SSL having a molecular weight of 40000 was used as the HPC.

### Inventive Example 4

20 parts by mass of VA were gradually added to 70 parts by mass of pure water, and the solution was stirred to dissolve the VA. Thereafter, 5 parts by mass of TMP were added to the solution, and the solution was stirred to dissolve the TMP. Then, 5 parts by mass of αGR were gradually added to the solution, and the solution was stirred to dissolve the GR. In this manner, a protective film agent 23 according to Inventive Example 4 was obtained. SOKALAN (registered trademark in Japan) VA 64 P manufactured by BASF Corporation was used as the VA.

### Inventive Example 5

15 parts by mass of PVA were gradually added to 72 parts by mass of pure water, and the solution was stirred to dissolve the PVA. Thereafter, 8 parts by mass of TMP were added to the solution, and the solution was stirred to dissolve the TMP. Then, 5 parts by mass of αGR were gradually added to the solution, and the solution was stirred to dissolve the αGR. In this manner, a protective film agent 23 according to Inventive Example 5 was obtained. The degree of polymerization of the PVA used was 300, and the degree of saponification thereof was in the range from 78.5 mol % to 81.5 mol %.

### Inventive Example 6

13.5 parts by mass of PVP were gradually added to 60.0 parts by mass of pure water and 15.0 parts by mass of PGME, and the solution was stirred to dissolve the PVP. Thereafter, 6.5 parts by mass of TMP were added to the solution, and the solution was stirred to dissolve the TMP. Then, 5.0 parts by mass of αGR were gradually added to the solution, and the solution was stirred to dissolve the αGR. In this manner, a protective film agent 23 according to Inventive Example 6 was obtained. PVP-K30 having a K value in the range from 27 to 33 was used as the PVP.

### Inventive Example 7

5.4 parts by mass of PVP were gradually added to 75.0 parts by mass of pure water and 15.0 parts by mass of PGME, and the solution was stirred to dissolve the PVP. Thereafter, 2.6 parts by mass of TMP were added to the solution, and the solution was stirred to dissolve the TMP. Then, 2.0 parts by mass of αGR were gradually added to the solution, and the solution was stirred to dissolve the αGR. In this manner, a protective film agent 23 according to Inventive Example 7 was obtained. PVP-K90 having a K value in the range from 92 to 96 was used as the PVP.

### Inventive Example 8

15 parts by mass of PVA were gradually added to 75 parts by mass of pure water, and the solution was stirred to dissolve the PVA. Thereafter, 5 parts by mass of glycerin (hereinafter referred to as GLR) were added to the solution, and the solution was stirred to dissolve the GLR. Then, 5 parts by mass of αGR were gradually added to the solution, and the solution was stirred to dissolve the αGR. In this manner, a protective film agent 23 according to Inventive Example 8 was obtained. The degree of polymerization of the PVA used was 300, and the degree of saponification thereof was in the range from 78.5 mol % to 81.5 mol %. GLR manufactured by FUJIFILM Wako Pure Chemical Corporation was used as the GLR.

### Inventive Example 9

15 parts by mass of PVA were gradually added to 75 parts by mass of pure water, and the solution was stirred to dissolve the PVA. Thereafter, 5 parts by mass of polyethylene glycol (hereinafter referred to as PEG) were added to the solution, and the solution was stirred to dissolve the PEG. Then, 5 parts by mass of αGR were gradually added to the solution, and the solution was stirred to dissolve the αGR. In this manner, a protective film agent 23 according to Inventive Example 9 was obtained. The degree of polymerization of the PVA used was 300, and the degree of saponification thereof was in the range from 78.5 mol % to 81.5 mol %. The average molecular weight of the PEG used was approximately 200 (in the range from 180 to 220).

### Inventive Example 10

15 parts by mass of PVA were gradually added to 75 parts by mass of pure water, and the solution was stirred to dissolve the PVA. Thereafter, 5 parts by mass of PEG were added to the solution, and the solution was stirred to dissolve the PEG. Then, 5 parts by mass of αGR were gradually added to the solution, and the solution was stirred to dissolve the αGR. In this manner, a protective film agent 23 according to Inventive Example 10 was obtained. The degree of polymerization of the PVA used was 300, and the degree of saponification thereof was in the range from 78.5 mol % to 81.5 mol %. The average molecular weight of the PEG used was approximately 1000 (in the range from 900 to 1100).

### Inventive Example 11

15 parts by mass of PVP were gradually added to 78 parts by mass of pure water, and the solution was stirred to dissolve the PVP. Thereafter, 5 parts by mass of TMP were added to the solution, and the solution was stirred to dissolve the TMP. Then, 2 parts by mass of αGR were gradually added to the solution, and the solution was stirred to dissolve the αGR. In this manner, a protective film agent 23 according to Inventive Example 11 was obtained. PVP-K50 having a K value in the range from 48 to 52 was used as the PVP.

### Comparative Example 1

15 parts by mass of PVP were gradually added to 80 parts by mass of pure water, and the solution was stirred to dissolve the PVP. Then, 5 parts by mass of αGR were gradually added to the solution, and the solution was stirred to dissolve the αGR. In this manner, a protective film agent according to Comparative Example 1 was obtained. PVP-K50 having a K value in the range from 48 to 52 was used as the PVP.

### Comparative Example 2

15 parts by mass of PVA were gradually added to 80 parts by mass of pure water, and the solution was stirred to dissolve the PVA. Then, 5 parts by mass of αGR were gradually added to the solution, and the solution was stirred to dissolve the αGR. In this manner, a protective film agent according to Comparative Example 2 was obtained. The degree of polymerization of the PVA used was 300, and the degree of saponification thereof was in the range from 78.5 mol % to 81.5 mol %.

### Comparative Example 3

15 parts by mass of HPC were gradually added to 80 parts by mass of pure water, and the solution was stirred to dissolve the HPC. Then, 5 parts by mass of αGR were gradually added to the solution, and the solution was stirred to dissolve the αGR. In this manner, a protective film agent according to Comparative Example 3 was obtained. HPC-SSL having a molecular weight of 40000 was used as the HPC.

### Comparative Example 4

20 parts by mass of VA were gradually added to 75 parts by mass of pure water, and the solution was stirred to dissolve the VA. Then, 5 parts by mass of αGR were gradually added to the solution, and the solution was stirred to dissolve the αGR. In this manner, a protective film agent according to Comparative Example 4 was obtained. SOKALAN (registered trademark in Japan) VA 64 P manufactured by BASF Corporation was used as the VA.

### Comparative Example 5

15 parts by mass of PVA were gradually added to 71 parts by mass of pure water, and the solution was stirred to dissolve the PVA. Thereafter, 9 parts by mass of TMP were added to the solution, and the solution was stirred to dissolve the TMP. Then, 5 parts by mass of αGR were gradually added to the solution, and the solution was stirred to dissolve the αGR. In this manner, a protective film agent according to Comparative Example 5 was obtained. The degree of polymerization of the PVA used was 300, and the degree of saponification thereof was in the range from 78.5 mol % to 81.5 mol %.

### Comparative Example 6

13.5 parts by mass of PVP were gradually added to 66.5 parts by mass of pure water and 15.0 parts by mass of PGME, and the solution was stirred to dissolve the PVP. Then, 5.0 parts by mass of αGR were gradually added to the solution, and the solution was stirred to dissolve the αGR. In this manner, a protective film agent according to Comparative Example 6 was obtained. PVP-K30 having a K value in the range from 27 to 33 was used as the PVP.

### Comparative Example 7

5.4 parts by mass of PVP were gradually added to 77.6 parts by mass of pure water and 15.0 parts by mass of PGME, and the solution was stirred to dissolve the PVP. Then, 2.0 parts by mass of αGR were gradually added to the solution, and the solution was stirred to dissolve the αGR. In this manner, a protective film agent according to Comparative Example 7 was obtained. PVP-K90 having a K value in the range from 92 to 96 was used as the PVP.

The mass ratios (unit: wt %) of the respective protective film agents (Inventive Examples 1 through 11 and Comparative Examples 1 through 7) are indicated in Table 1 and Table 2 below. Table 1 and Table 2 also indicate the names of materials in the parentheses below the numerical values, and bars representing no corresponding materials contained. Table 1 and Table 2 further indicate ratios R of the mass of the plasticizer to the mass of the water-soluble resin in the second columns to the rightmost columns. Each of the ratios R refers to a percentage and is calculated according to {plasticizer (wt %)/water-soluble resin (wt %)}×100. The numerical values representing the ratios R is rounded up to the closest whole number.

In Table 1 and Table 2, the rightmost columns indicate processing results. The processing results were obtained by observing the states of the protective films prior to cleaning step S40 after covering step S10, irradiating step S20, and plasma etching step S30 were successively carried out on the protective film agents. A indicates that the processing result was good whereas B indicates that the processing result was not good.

TABLE 1

| Inventive | Water-soluble | Light absorbing | Plasticizer | Organic | | Ratio | Processing |
|---|---|---|---|---|---|---|---|
| Example | resin [wt %] | agent [wt %] | [wt %] | solution [wt %] | Solvent [wt %] | R [%] | result |
| 1 | 15 (PVP) | 5 (αGR) | 5 (TMP) | — | 75 (pure water) | 33 | A |
| 2 | 15 (PVA) | 5 (αGR) | 5 (TMP) | — | 75 (pure water) | 33 | A |
| 3 | 15.00 (HPC) | 5.00 (αGR) | 2.25 (TMP) | — | 77.75 (pure water) | 15 | A |
| 4 | 20 (VA) | 5 (αGR) | 5 (TMP) | — | 70 (pure water) | 25 | A |
| 5 | 15 (PVA) | 5 (αGR) | 8 (TMP) | — | 72 (pure water) | 53 | A |
| 6 | 13.5 (PVP) | 5.0 (αGR) | 6.5 (TMP) | 15.0 (PGME) | 60.0 (pure water) | 48 | A |
| 7 | 5.4 (PVP) | 2.0 (αGR) | 2.6 (TMP) | 15.0 (PGME) | 75.0 (pure water) | 48 | A |
| 8 | 15 (PVA) | 5 (αGR) | 5 (GLR) | — | 75 (pure water) | 33 | A |
| 9 | 15 (PVA) | 5 (αGR) | 5 (PEG) | — | 75 (pure water) | 33 | A |
| 10 | 15 (PVA) | 5 (αGR) | 5 (PEG) | — | 75 (pure water) | 33 | A |
| 11 | 15 (PVP) | 2 (αGR) | 5 (TMP) | — | 78 (pure water) | 33 | A |

TABLE 2

| Comparative | Water-soluble | Light absorbing | Plasticizer | Organic | | Ratio | Processing |
|---|---|---|---|---|---|---|---|
| Example | resin [wt %] | agent [wt %] | [wt %] | solution [wt %] | Solvent [wt %] | R [%] | result |
| 1 | 15 (PVP) | 5 (αGR) | — | — | 80 (pure water) | 0 | B |
| 2 | 15 (PVA) | 5 (αGR) | — | — | 80 (pure water) | 0 | B |
| 3 | 15 (HPC) | 5 (αGR) | — | — | 80 (pure water) | 0 | B |
| 4 | 20 (VA) | 5 (αGR) | — | — | 75 (pure water) | 0 | B |
| 5 | 15 (PVA) | 5 (αGR) | 9 (TMP) | — | 71 (pure water) | 60 | B |
| 6 | 13.5 (PVP) | 5.0 (αGR) | — | 15.0 (PGME) | 66.5 (pure water) | 0 | B |
| 7 | 5.4 (PVP) | 2.0 (αGR) | — | 15.0 (PGME) | 77.6 (pure water) | 0 | B |

Covering step S10 in Inventive Examples 1 through 11 and Comparative Examples 1 through 7 will be described below. In covering step S10, protective films were formed on the face sides 11a of the workpieces 11 free of the devices 15, i.e., bare silicon wafers, from 30 mL of the respective protective film agents in the spin coating process. Rotational speeds (rpm) and times (s) of the spinner table 4 used in covering step S10 are indicated in Table 3 and Table 4 below. Table 3 and Table 4 also indicate thicknesses (μm) and hardnesses (GPa) of the protective films formed from the respective protective film agents.

TABLE 3

| | | Thickness | | |
|---|---|---|---|---|
| | Rotational | of | Hardness of | |
| Inventive | speed (rpm) | protective | protective | Absorbance |
| Example | and time (s) | film (μm) | film (GPa) | (Abs) |
| 1 | 2000 rpm for 90 | 3.95 | 0.1300 | 5.294 |
| | seconds | | | |
| 2 | 900 rmp for 60 | 4.09 | 0.0093 | 5.381 |
| | seconds, then | | | |
| | 2000 rpm for 60 | | | |
| | seconds | | | |
| 3 | 1250 rpm for 60 | 3.96 | 0.0290 | 5.188 |
| | seconds, then | | | |
| | 2000 rpm for 60 | | | |
| | seconds | | | |
| 4 | 1100 rpm for 60 | 4.03 | 0.0860 | 5.360 |
| | seconds, then | | | |
| | 2000 rpm for 60 | | | |
| | seconds | | | |
| 5 | 1100 rpm for 60 | 4.03 | 0.0110 | 5.004 |
| | seconds, then | | | |
| | 2000 rpm for 60 | | | |
| | seconds | | | |
| 6 | 550 rpm for 60 | 3.98 | 0.0760 | 5.294 |
| | seconds, then 950 | | | |
| | rpm for 60 | | | |
| | seconds, then | | | |
| | 2000 rpm for 60 | | | |
| | seconds | | | |
| 7 | 400 rpm for 60 | 2.02 | 0.1200 | 2.130 |
| | seconds, then 800 | | | |
| | rpm for 60 | | | |
| | seconds, then | | | |
| | 2000 rpm for 60 | | | |
| | seconds | | | |
| 8 | 900 rpm for 60 | 3.99 | 0.0110 | 5.264 |
| | seconds, then | | | |
| | 2000 rpm for 60 | | | |
| | seconds | | | |
| 9 | 900 rpm for 60 | 4.01 | 0.0130 | 5.237 |
| | seconds, then | | | |
| | 2000 rpm for 60 | | | |
| | seconds | | | |
| 10 | 900 rpm for 60 | 3.97 | 0.0290 | 5.189 |
| | seconds, then | | | |
| | 2000 rpm for 60 | | | |
| | seconds | | | |
| 11 | 1150 rpm for 60 | 4.02 | 0.1100 | 2.126 |
| | seconds, then | | | |
| | 2000 rpm for 60 | | | |
| | seconds | | | |

TABLE 4

| | | Thickness | | |
|---|---|---|---|---|
| | Rotational | of | Hardness of | |
| Comparative | speed (rpm) | protective | protective | Absorbance |
| Example | and time (s) | film (μm) | film (GPa) | (Abs) |
| 1 | 1400 rpm for 60 | 3.95 | 0.1800 | 5.305 |
| | seconds, then | | | |
| | 2000 rpm for 60 | | | |
| | seconds | | | |
| 2 | 500 rmp for 60 | 3.97 | 0.2500 | 5.307 |
| | seconds, then | | | |
| | 1100 rpm for 60 | | | |
| | seconds, then | | | |
| | 2000 rpm for 60 | | | |
| | seconds | | | |
| 3 | 1100 rpm for 60 | 3.91 | 0.1800 | 5.250 |
| | seconds, then | | | |
| | 2000 rpm for 60 | | | |
| | seconds | | | |
| 4 | 600 rpm for 60 | 3.97 | 0.2400 | 5.230 |
| | seconds, then | | | |
| | 1200 rpm for 60 | | | |
| | seconds, then | | | |
| | 2000 rpm for 60 | | | |
| | seconds | | | |
| 5 | 1150 rpm for 60 | 3.97 | 0.0089 | 5.159 |
| | seconds, then | | | |
| | 2000 rpm for 60 | | | |
| | seconds | | | |
| 6 | 400 rpm for 120 | 3.61 | 0.3000 | 5.324 |
| | seconds, then | | | |
| | 2000 rpm for 60 | | | |
| | seconds | | | |
| 7 | 400 rpm for 120 | 2.02 | 0.3200 | 2.090 |
| | seconds, then | | | |
| | 2000 rpm for 60 | | | |
| | seconds | | | |

### (Hardness)

The hardnesses indicated in Table 3 and Table 4 were measured using Nano Indenter G200X which is a thin film mechanical property assessing apparatus manufactured by KLA-Tencor Corporation. InForce50 of relatively high resolution was incorporated in the head of the thin film mechanical property assessing apparatus. The thin film mechanical property assessing apparatus used a triangular pyramid indenter of diamond, and measured the protective films at room temperature under atmospheric pressure. A nanoindentation technique, particularly a continuous stiffness measurement (CSM) technique, was used to measure the protective films.

According to the continuous stiffness measurement technique, a first load that increases linearly with time and a second load that varies periodically were superimposed on the triangular pyramid indenter, pressing the protective films. When the second load varied periodically, the triangular pyramid indenter was displaced by an amplitude of 2 nm. The hardness of a sample was calculated as an average value of the hardnesses measured at five spots on the sample. (Absorbance)

The absorbance indicated in Table 3 and Table 4 was measured using ultraviolet and visible spectrophotometer UV-2700 manufactured by Shimadzu Corporation. Specifically, the respective protective film agents according to Inventive Examples 1 through 11 and Comparative Examples 1 through 7 were diluted 200 times with pure water, and the diluted solutions were sealed in respective prismatic cells of quartz. Thereafter, the protective film agents sealed in the cells were measured for their absorption spectrums. The cells had a length, i.e., a thickness, of 1 cm along the optical path.

### (Mask Formation)

The protective films formed from the protective film agents were processed with the pulsed laser beam L having the wavelength of 355 nm, making respective masks through which the projected processing lines 13 of the workpieces 11 were exposed. Processing conditions were as follows.
Average output power: 0.7 W
Beam spot diameter: 15 μm (the diameter on the upper surface of the protective film)
Repetitive frequency: 200 kHz
Pulse duration: 9 ps
Processing feed speed: 600 mm/s

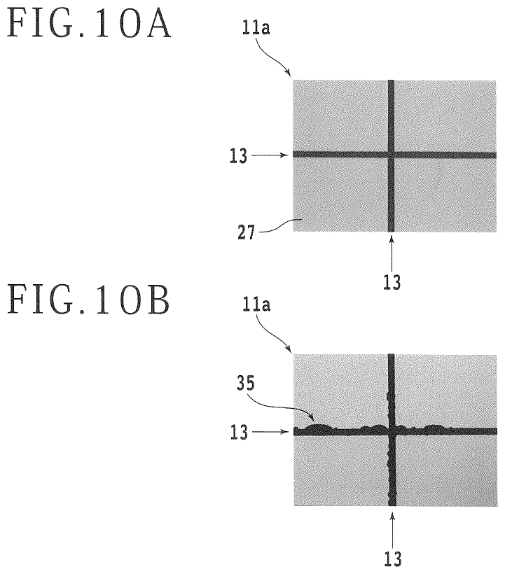

FIG. 10A is a photographic representation of a portion of a face side 11a of a workpiece 11 after a mask 27 was formed thereon from the protective film agent 23 according to Inventive Example 1 and the workpiece 11 was processed by plasma etching. FIG. 10B is a photographic representation of a portion of a face side 11a of a workpiece 11 after a mask was formed thereon from the protective film agent according to Comparative Example 1 and the workpiece 11 was processed by plasma etching.

In FIG. 10B, the plasma 29 entered between the face side 11a and the protective film at the edges of the grooves formed in the protective film along the projected processing lines 13, developing undercut regions 35 where the face side 11a was etched. In FIG. 10B and other similar figures, only some undercut regions 35 are illustrated. This also holds true for the following

### FIGURES

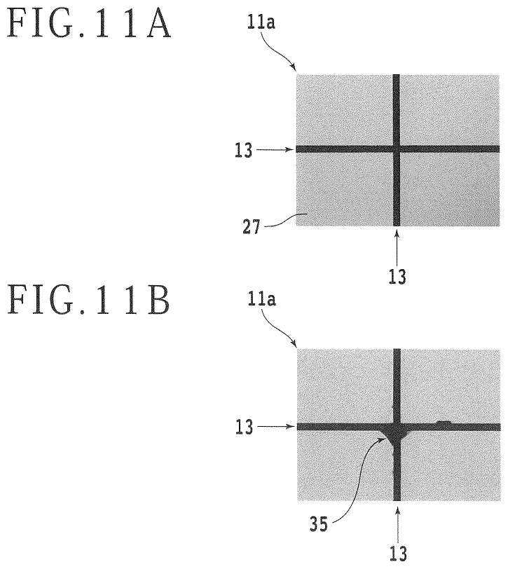

FIG. 11A is a photographic representation of a portion of a face side 11a of a workpiece 11 after a mask 27 was formed thereon from the protective film agent 23 according to Inventive Example 2 and the workpiece 11 was processed by plasma etching. FIG. 11B is a photographic representation of a portion of a face side 11a of a workpiece 11 after a mask was formed thereon from the protective film agent according to Comparative Example 2 and the workpiece 11 was processed by plasma etching.

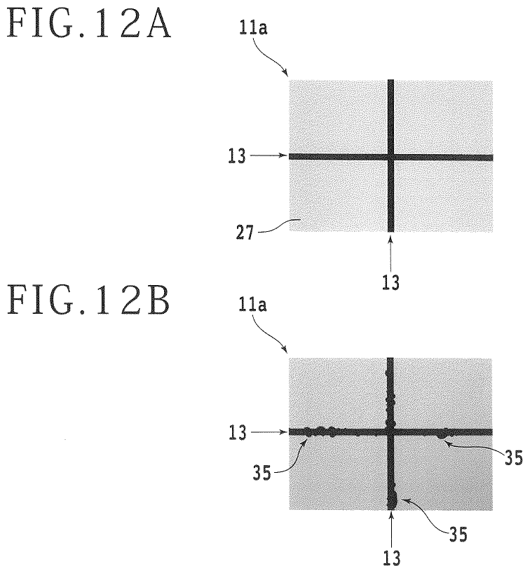

FIG. 12A is a photographic representation of a portion of a face side 11a of a workpiece 11 after a mask 27 was formed thereon from the protective film agent 23 according to Inventive Example 3 and the workpiece 11 was processed by plasma etching. FIG. 12B is a photographic representation of a portion of a face side 11a of a workpiece 11 after a mask was formed thereon from the protective film agent according to Comparative Example 3 and the workpiece 11 was processed by plasma etching.

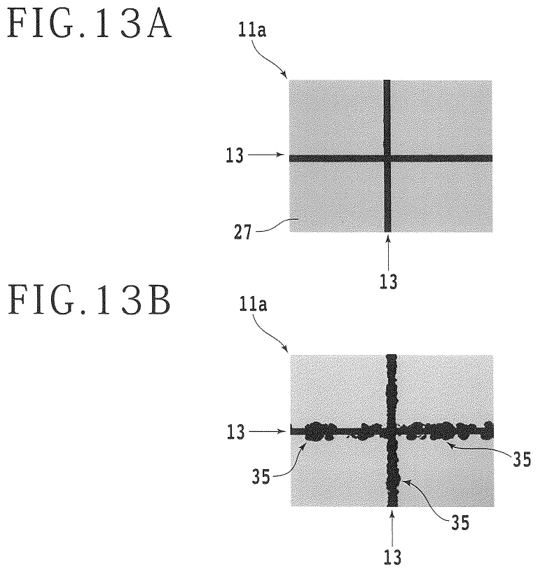

FIG. 13A is a photographic representation of a portion of a face side 11a of a workpiece 11 after a mask 27 was formed thereon from the protective film agent 23 according to Inventive Example 4 and the workpiece 11 was processed by plasma etching. FIG. 13B is a photographic representation of a portion of a face side 11a of a workpiece 11 after a mask was formed thereon from the protective film agent according to Comparative Example 4 and the workpiece 11 was processed by plasma etching.

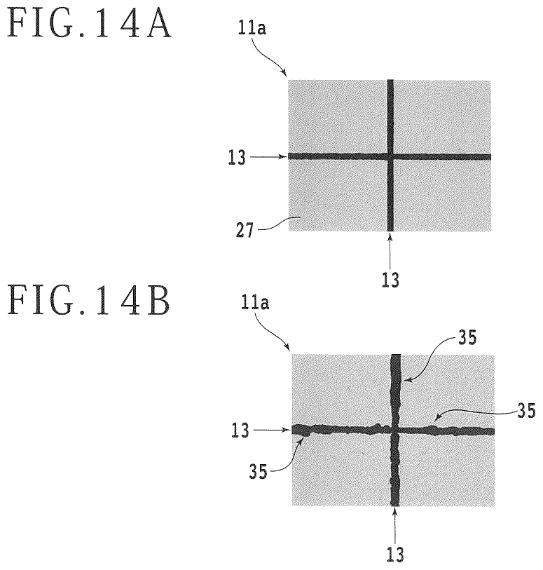

FIG. 14A is a photographic representation of a portion of a face side 11a of a workpiece 11 after a mask 27 was formed thereon from the protective film agent 23 according to Inventive Example 5 and the workpiece 11 was processed by plasma etching. FIG. 14B is a photographic representation of a portion of a face side 11a of a workpiece 11 after a mask was formed thereon from the protective film agent according to Comparative Example 5 and the workpiece 11 was processed by plasma etching.

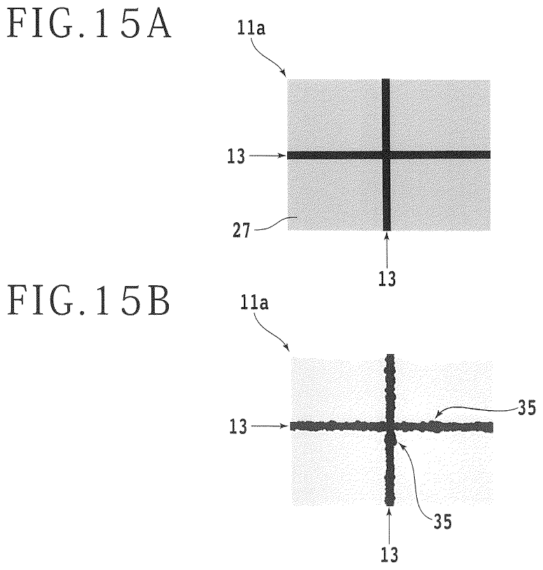

FIG. 15A is a photographic representation of a portion of a face side 11a of a workpiece 11 after a mask 27 was formed thereon from the protective film agent 23 according to Inventive Example 6 and the workpiece was processed by plasma etching. FIG. 15B is a photographic representation of a portion of a face side 11a of a workpiece 11 after a mask was formed thereon from the protective film agent according to Comparative Example 6 and the workpiece 11 was processed by plasma etching.

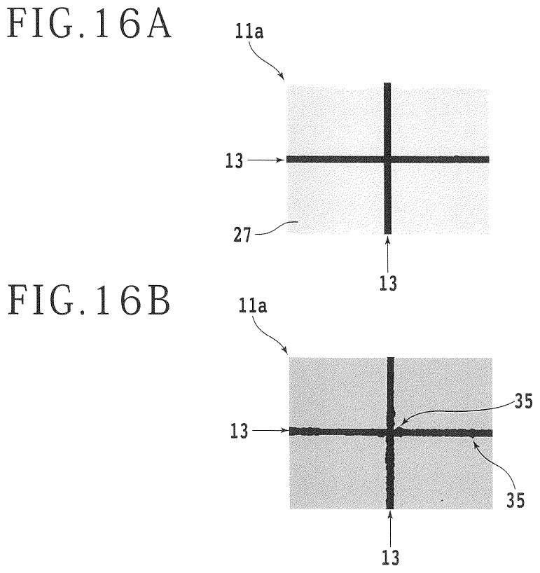

FIG. 16A is a photographic representation of a portion of a face side 11a of a workpiece 11 after a mask 27 was formed thereon from the protective film agent 23 according to Inventive Example 7 and the workpiece 11 was processed by plasma etching. FIG. 16B is a photographic representation of a portion of a face side 11a of a workpiece 11 after a mask was formed thereon from the protective film agent according to Comparative Example 7 and the workpiece 11 was processed by plasma etching.

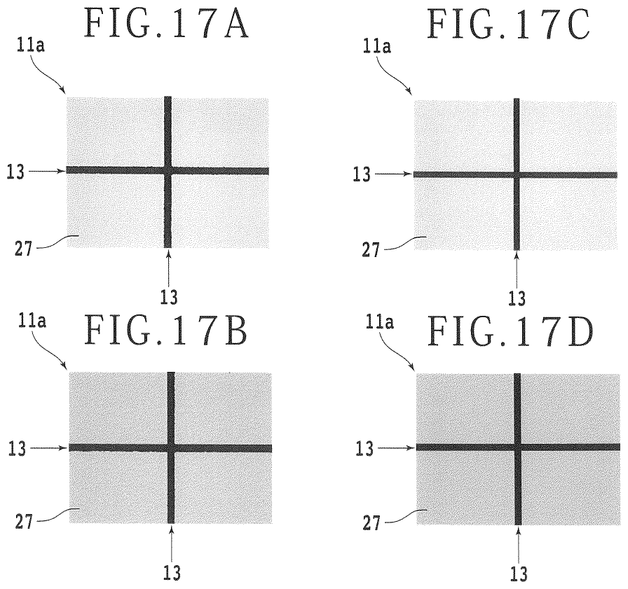

FIG. 17A is a photographic representation of a portion of a face side 11a of a workpiece 11 after a mask 27 was formed thereon from the protective film agent 23 according to Inventive Example 8 and the workpiece 11 was processed by plasma etching. FIG. 17B is a photographic representation of a portion of a face side 11a of a workpiece 11 after a mask 27 was formed thereon from the protective film agent according to Inventive Example 9 and the workpiece 11 was processed by plasma etching.

FIG. 17C is a photographic representation of a portion of a face side 11a of a workpiece 11 after a mask 27 was formed thereon from the protective film agent 23 according to Inventive Example 10 and the workpiece 11 was processed by plasma etching. FIG. 17D is a photographic representation of a portion of a face side 11a of a workpiece 11 after a mask 27 was formed thereon from the protective film agent 23 according to Inventive Example 11 and the workpiece 11 was processed by plasma etching.

According to Comparative Examples 1 through 7 illustrated respectively in FIGS. 10B, 11B, 12B, 13B, 14B, 15B, and 16B, the plasma 29 entered between the face side 11a and the protective film at the edges of the grooves formed in the protective film along the projected processing lines 13 and in the vicinity of the crossing of two grooves, developing undercut regions 35 where the face side 11a was etched.

According to Comparative Examples 4 through 7 illustrated respectively in FIGS. 13B, 14B, 15B, and 16B, in particular, the undercut regions 35 at the edges of the grooves formed in the protective film along the projected processing lines 13 are of various sizes entirely along longitudinal directions of the grooves.

It is apparent from a comparison with Comparative Examples 1 through 7 illustrated respectively in FIGS. 10B, 11B, 12B, 13B, 14B, 15B, and 16B that Inventive Examples 1 through 11 illustrated respectively in FIGS. 10A, 11A, 12A, 13A, 14A, 15A, 16A, and 17A through 17D achieved much higher quality with which the workpieces 11 were processed by plasma etching.

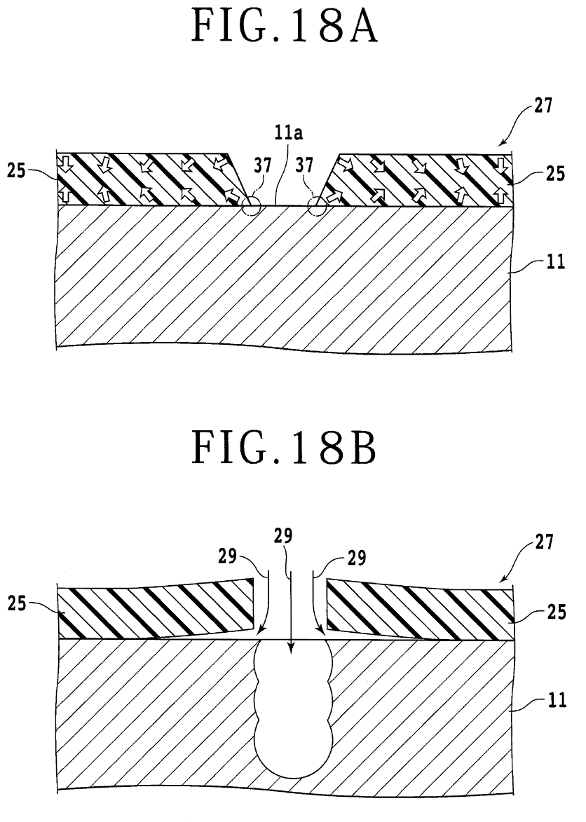

Using the protective film agents 23 according to Inventive Examples 1 through 11, the protective films 25 formed therefrom were sufficiently reduced in hardness, i.e., made pliable, so that their shrinkage stress was reduced. Therefore, it is considered that the intimate contact between the protective films 25 and the face sides 11a of the workpieces 11 was increased, making it possible to increase the quality with which the workpieces 11 were processed by plasma etching. If the hardness of a protective film is not sufficiently reduced, then the plasma 29 enters between the face side 11a and the protective film in plasma etching step S30 (see FIGS. 18A and 18B).

FIG. 18A schematically illustrates in fragmentary cross section the manner in which the protective film shrinks in Comparative Example. As illustrated in FIG. 18A, the protective film gradually shrinks, though slightly, progressively in the directions indicated by the arrows even after covering step S10.

Portions of the protective film at corners 37 thereof on the face side 11a do not shrink as they are held in contact with the face side 11a. Consequently, shrinkage stresses tend to be accumulated in the corners 37. As described above, a shrinkage stress acting on the protective film is proportional to the product of the elastic modulus of the protective film and the amount of shrinkage strain of the protective film, and the elastic modulus of the protective film is substantially commensurate with the hardness of the protective film. Therefore, the higher the hardness of the protective film is, the larger the shrinkage stress of the protective film is.

According to Comparative Examples 1 through 7 where the protective films have relatively large hardnesses, the protective films are likely to peel off partially on account of laser ablation. According to Inventive Examples 1 through 11 where the protective films have relatively small hardnesses, the protective films undergo small shrinkage stresses and hence tend to peel off in smaller ranges than the protective films according to Comparative Examples 1 through 7 or substantially not to peel off.

When the protective film peels off, as illustrated in FIG. 18B, since the plasma 29 enters between the protective film and the face side 11a in plasma etching step S30, the workpiece 11 is undesirably etched in regions where it should not be etched. Those undesirably etched regions of the workpiece 11 are depicted as the undercut regions 35 referred to above in FIGS. 10B, 11B, 12B, 13B, 14B, 15B, and 16B, and tend to cause a reduction in the quality with which the workpiece 11 is processed by plasma etching. FIG. 18B schematically illustrates in fragmentary cross section, the manner in which the plasma 29 enters between the protective film according to either one of Comparative Examples 1 through 7 and the face side 11a of the workpiece 11.

Since the protective film 25 according to the present embodiment contains the plasticizer, the protective film 25 is more pliable than if it is free of the plasticizer. It is thus considered that the shrinkage stress of the protective film 25 is reduced.

Research conducted by the applicant has revealed that the protective film agent 23 that contains the plasticizer has a more tendency to decompose and sublimate upon laser ablation than plasticizer-free protective film agents, and is assumed to be easily removed by laser ablation. The applicant verified the assumption by performing laser ablation on the protective film 25 formed from the protective film agent 23 according to Inventive Example 2 and the protective film formed from the protective film agent according to Comparative Example 2 under identical processing conditions.

Specifically, after covering step S10 and irradiating step S20, a scanning electron microscope (SEM) analysis and an energy dispersive X-ray spectroscopy (EDX) analysis were performed on the regions where the protective films were removed, using Miniscope (registered trademark in Japan) TM3030Plus sold by Hitachi High-Tech Corporation. According to the EDX analysis, the peak intensities of characteristic X-rays corresponding various elements included in a measurement target are measured as counts per second (cps). According to the EDX analysis, the ratio (C/Si) of counts per second of the peak intensity with respect to carbon (C) stemming mainly from each of the protective films to counts per second of the peak intensity with respect to silicon (Si) stemming mainly from the workpiece 11 was calculated.

Regarding the regions where the protective film 25 formed from the protective film agent 23 according to Inventive Example 2 was removed, the ratio of C/Si was 0.496 (=6840/13784). On the other hand, regarding the regions where the protective film formed from the protective film agent according to Comparative Example 2 was removed, the ratio of C/Si was 0.597 (=7572/12679).

The result means that the protective film 25 formed from the protective film agent 23 according to Inventive Example 2 causes less residuals stemming from the protective film 25 than the protective film formed from the protective film agent according to Comparative Example 2. In other words, the protective film agent 23 having the plasticizer is easier to remove by way of laser ablation.

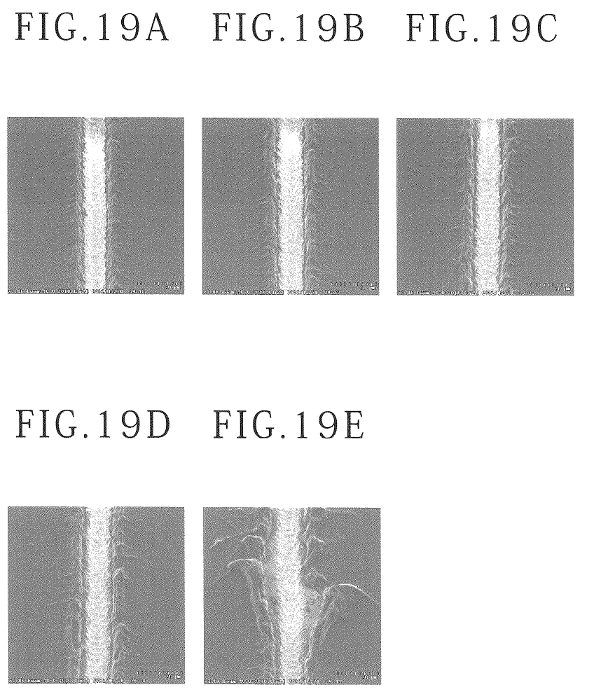

However, too much plasticizer in the protective film agent, though it may pose no problem as to the intimate contact between the protective film and the face side 11a of the workpiece 11 prior to irradiating step S20, is problematic in that since the pliability of the protective film becomes excessively high, the edges of the grooves formed in the protective film along the projected processing lines 13 in irradiating step S20 are peeled off by being turned up. The applicant conducted an experiment in which laser ablation was performed at different ratios R of the plasticizer in the protective film agent in respective examples. FIG. 19A is a photographic representation of a portion of the mask 27 formed from the protective film agent 23 containing a plasticizer at a first ratio.

The example illustrated in FIG. 19A used the protective film agent 23 according to Inventive Example 2 that contained 15 wt % of PVA (water-soluble resin), 5 wt % of αGR (light absorbing agent), 5 wt % of TMP (plasticizer), and 75 wt % of pure water (solvent). As described above, in Inventive Example 2, the ratio R (i.e., the first ratio) of the mass of the plasticizer to the mass of the water-soluble resin was approximately 33% (=(5/15)×100).

FIG. 19B is a photographic representation of a portion of the mask 27 formed from the protective film agent 23 containing a plasticizer at a second ratio. The example illustrated in FIG. 19B used a protective film agent 23 that contained 15 wt % of PVA (water-soluble resin), 5 wt % of αGR (light absorbing agent), 6 wt % of TMP (plasticizer), and 74 wt % of pure water (solvent). The ratio R (i.e., the second ratio) of the mass of the plasticizer to the mass of the water-soluble resin was approximately 40% (=(6/15)×100).

FIG. 19C is a photographic representation of a portion of the mask 27 formed from the protective film agent 23 containing a plasticizer at a third ratio. The example illustrated in FIG. 19C used a protective film agent 23 that contained 15 wt % of PVA (water-soluble resin), 5 wt % of αGR (light absorbing agent), 7 wt % of TMP (plasticizer), and 73 wt % of pure water (solvent). The ratio R (i.e., the third ratio) of the mass of the plasticizer to the mass of the water-soluble resin was approximately 47% (=(7/15)×100).

FIG. 19D is a photographic representation of a portion of the mask 27 formed from the protective film agent 23 containing a plasticizer at a fourth ratio. The example illustrated in FIG. 19D used a protective film agent 23 that contained 15 wt % of PVA (water-soluble resin), 5 wt % of αGR (light absorbing agent), 8 wt % of TMP (plasticizer), and 72 wt % of pure water (solvent). The ratio R (i.e., the fourth ratio) of the mass of the plasticizer to the mass of the water-soluble resin was approximately 53% (=(8/15)×100).

FIG. 19E is a photographic representation of a portion of the mask 27 formed from the protective film agent containing a plasticizer at a fifth ratio. The example illustrated in FIG. 19E used a protective film agent according to Comparative Example 5 that contained 15 wt % of PVA (water-soluble resin), 5 wt % of αGR (light absorbing agent), 9 wt % of TMP (plasticizer), and 71 wt % of pure water (solvent). The ratio R (i.e., the fifth ratio) of the mass of the plasticizer to the mass of the water-soluble resin was approximately 60% (=(9/15)×100).

As is obvious from the photographic representation of FIG. 19E, when the ratio R of the mass of the plasticizer to the mass of the water-soluble resin exceeds 60%, the pliability of the protective film becomes excessively high, so that the edges of the grooves formed in the protective film along the projected processing lines 13 are peeled off by being turned up. It is considered that the peeled-off edges of the grooves led to the development of the undercut regions 35 illustrated in FIG. 14B.

According to Inventive Example 3 (the protective film agent 23 contains 15.00 wt % of HPC and 2.25 wt % of TMP) indicated in Table 1, the ratio R of the mass of the plasticizer to the mass of the water-soluble resin is 15%. In view of the foregoing, it can be said that an appropriate range of the ratio R of the mass of the plasticizer to the mass of the water-soluble resin is from 15% to less than 60%, or more preferably from 15% to 53%.

The structural and methodical details according to the present embodiment may be changed or modified without departing the scope of the present invention. For example, the protective film agent 23 may not necessarily contain the plasticizer providing the hardness of the protective film 25 is in the range from 0.0093 GPa to 0.13 GPa.

Furthermore, a low-molecular compound that is different from the plasticizer described above may be mixed with the protective film agent 23 or the structure of the water-soluble rein of the protective film agent 23 may be modified, for example, to make the protective film 25 pliable to the extent that the hardness of the protective film 25 is in the range from 0.0093 GPa to 0.13 GPa. As a result, the intimate contact between the protective film 25 and the face side 11a of the workpiece 11 may be increased.

At any rate, insofar as the hardness of the protective film 25 is in the range from 0.0093 GPa to 0.13 GPa, the intimate contact between the protective film 25 and the face side 11a of the workpiece 11 is increased to increase the quality with which the workpiece 11 is processed by plasma etching.

The protective film 25 is applicable to a laser dicing process for performing laser ablation on the workpiece 11 with the laser beam L whose wavelength is absorbable by the workpiece 11, rather than the plasma etching process for performing plasma etching on the workpiece 11 in plasma etching step S30. In other words, the protective film agent 23 can function as a protective film agent for laser dicing. The protective film 25 can similarly function as a protective film for laser dicing. For performing laser ablation such as laser dicing, first, the face side 11a of the workpiece 11 is covered with the protective film 25 in covering step S10.

Then, in irradiating step S20, the workpiece 11 is irradiated with the laser beam L along the projected processing lines 13, forming grooves to a predetermined depth in the workpiece 11 along the projected processing lines 13 or severing the workpiece 11 along the projected processing lines 13. After irradiating step S20, plasma etching step S30 is skipped, and the protective film 25 is cleaned off the workpiece 11 in cleaning step S40. The protective film 25 prevents debris produced by laser ablation from being attached to the devices 15, and is then removed together with the debris in cleaning step S40.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A protective film to be disposed on a surface of a workpiece, wherein the protective film has a hardness in a range from 0.0093 GPa to 0.13 GPa.

2. A protective film agent comprising:
a water-soluble resin;
a light absorbing agent;
a plasticizer; and
a solvent in which the water-soluble resin, the light absorbing agent, and the plasticizer are dissolve, wherein
a ratio of a mass of the plasticizer to a mass of the water-soluble resin is in a range from 15% to 53%, and a protective film formed from the protective film agent has a hardness in a range from 0.0093 GPa to 0.13 GPa.

3. The protective film agent according to claim 2, wherein
the water-soluble resin is at least one selected from a group consisting of polyvinyl alcohol, a vinyl acetate-vinyl pyrrolidone copolymer, and polyvinyl pyrrolidone, and
the plasticizer is trimethylol propane.

4. The protective film agent according to claim 2, wherein the solvent includes water, and a ratio of a mass of water to a mass of the protective film agent is 50% or more.

5. A method of processing a workpiece, comprising:
a covering step of covering a surface of the workpiece with a protective film having a hardness in a range from 0.0093 GPa to 0.13 GPa;
after the covering step, an irradiating step of irradiating the protective film along projected processing lines established on the workpiece with a pulsed laser beam having a wavelength absorbable by the protective film, thereby removing portions of the protective film along the projected processing lines to expose portions of the workpiece; and,
after the irradiating step, a plasma etching step of performing plasma etching on the exposed portions of the workpiece using the protective film as a mask.
